(19) United States
(12) Patent Application Publication
(10) Pub. No.: US 2025/0244425 A1
(43) Pub. Date: Jul. 31, 2025

(54) STATIC FIELD ADJUSTMENT APPARATUS AND MAGNETIC RESONANCE IMAGING SYSTEM

(71) Applicant: Canon Medical Systems Corporation, Otawara-shi (JP)

(72) Inventors: Takehiro SHIBUYA, Nasushiobara (JP); Yoshitomo SAKAKURA, Nasushiobara (JP); Katsutoshi MIZUNO, Nasushiobara (JP); Michiru KAJIWARA, Nasushiobara (JP)

(73) Assignee: Canon Medical Systems Corporation, Otawara-shi (JP)

(21) Appl. No.: 19/040,262

(22) Filed: Jan. 29, 2025

(30) Foreign Application Priority Data
Jan. 30, 2024 (JP) 2024-011836
Feb. 2, 2024 (JP) 2024-015089
Feb. 5, 2024 (JP) 2024-015717
Oct. 25, 2024 (JP) 2024-188541

(51) Int. Cl. G01R 33/3815; G01R 33/3873

(52) U.S. Cl. CPC G01R 33/3815; G01R 33/3873

(57) ABSTRACT

According to one embodiment, a static field adjustment apparatus includes a plurality of holding members that hold a magnetic member for adjusting a distribution of a static magnetic field to be used in magnetic resonance imaging. All or some of the holding members are stacked in an axial direction and/or a radial direction of a magnet that has an annular shape and generates the static magnetic field, in a first space on an internal diameter side of the magnet.

### CROSS-REFERENCE TO RELATED APPLICATIONS

This application is based upon and claims the benefit of priority from Japanese Patent Applications No. 2024-011836, filed Jan. 30, 2024; No. 2024-015089, filed Feb. 2, 2024; No. 2024-015717, filed Feb. 5, 2024; and No. 2024-188541, filed Oct. 25, 2024, the entire contents of all of which are incorporated herein by reference.

### FIELD

Embodiments described herein relate generally to a static field adjustment apparatus and a magnetic resonance imaging system.

### BACKGROUND

In a magnetic resonance imaging system, magnetic members such as pieces of iron (iron shims) are used to adjust a distribution of a static magnetic field generated by a magnet. Since the locations of the pieces of iron are structurally restricted to specific locations, it might be difficult to adjust the static magnetic field distribution in a space outside the static field magnet in some cases.

### BRIEF DESCRIPTION OF DRAWINGS

FIG. 1 is a diagram showing an example structure of a magnetic resonance imaging system according to the present embodiment.

FIG. 2 is a perspective view of a gantry according to the present embodiment.

FIG. 3 is a schematic view of a Y-Z cross section of the gantry shown in FIG. 2.

FIG. 4 is a perspective view of one mode of a static field adjustment apparatus according to a first embodiment.

FIG. 5 is a perspective view of one mode of a holding member according to the first embodiment.

FIG. 6 is a plan view of the holding member shown in FIG. 5.

FIG. 7 is a view of an example of the support of a plurality of holding members by support members according to the first embodiment.

FIG. 8 is a drawing showing a Y-Z cross section of a first housing shown in FIG. 3.

FIG. 9 is a plan view of a holding member according to Modification 1 of the first embodiment.

FIG. 10 is a plan view of holding members according to Modification 2 of the first embodiment.

FIG. 11 is a drawing showing a plan view of a holding member according to Modification 3 of the first embodiment.

FIG. 12 is a drawing showing a plan view of a holding member according to Modification 4 of the first embodiment.

FIG. 13 is a perspective view of a static field adjustment apparatus according to Modification 5 of the first embodiment.

FIG. 14 is a drawing showing a Y-Z cross section of a first housing according to Modification 7 of the first embodiment.

FIG. 15 is a drawing showing a Y-Z cross section of a first housing according to Modification 8 of the first embodiment.

FIG. 16 is a perspective view of one mode of a holding member according to a second embodiment.

FIG. 17 is a developed view of the inner peripheral surface side of a lid portion according to the second embodiment.

FIG. 18 is a plan view of a lidded holding member according to the second embodiment.

FIG. 19 is a plan view of a lidded holding member according to Modification 1 of the second embodiment.

FIG. 20 is a plan view of a lidded holding member according to Modification 2 of the second embodiment.

FIG. 21 is a plan view of a lidded holding member according to Modification 3 of the second embodiment.

FIG. 22 is a plan view of a lidded holding member according to Modification 4 of the second embodiment.

FIG. 23 is a plan view of a lidded holding member according to Modification 5 of the second embodiment.

FIG. 24 is a plan view of a lidded holding member according to Modification 6 of the second embodiment.

FIG. 25 is a drawing showing a first layer of a first structural example of a static field adjustment apparatus according to a third embodiment.

FIG. 26 is a drawing showing a second layer of the first structural example of the static field adjustment apparatus according to the third embodiment.

FIG. 27 is a drawing showing the static field adjustment apparatus in which the first layer and the second layer are stacked according to the first structural example of the third embodiment.

FIG. 28 is a conceptual diagram in a case where the static field adjustment apparatus according to the third embodiment is wound.

FIG. 29 is a drawing showing a first layer of a second structural example of the static field adjustment apparatus according to the third embodiment.

FIG. 30 is a drawing showing a second layer of the second structural example of the static field adjustment apparatus according to the third embodiment.

FIG. 31 is a drawing showing the static field adjustment apparatus in which the first layer and the second layer are stacked according to the second structural example of the third embodiment.

FIG. 32 is a drawing showing a third structural example of the static field adjustment apparatus according to the third embodiment.

FIG. 33 is a drawing showing a fourth structural example of the static field adjustment apparatus according to the third embodiment.

FIG. 34 is a cross-sectional view taken along the central portion of the cylinder of a superconducting magnet, in the first structural example in a case where the static field adjustment apparatus according to the third embodiment is inserted into a gantry.

FIG. 35 is a drawing showing the positional relationship between a superconducting coil and the static field adjustment apparatus, in the first structural example in a case where the static field adjustment apparatus according to the third embodiment is inserted into the gantry.

FIG. 36 is a cross-sectional view taken along the central portion of the cylinder of a superconducting magnet, in the second structural example in a case where the static field adjustment apparatus according to the third embodiment is inserted into the gantry.

FIG. 37 is a drawing showing the positional relationship between a superconducting coil and the static field adjustment apparatus, in the second structural example in a case where the static field adjustment apparatus according to the third embodiment is inserted into the gantry.

FIG. 38 is a drawing showing the positional relationship between a superconducting coil and the static field adjustment apparatus, in the third structural example in a case where the static field adjustment apparatus according to the third embodiment is inserted into the gantry.

FIG. 39 is a drawing for explaining an example of aiding of arrangement of magnetic members in the static field adjustment apparatus according to the third embodiment.

FIG. 40 is a drawing showing an example of a static field adjustment apparatus according to a fourth embodiment.

### DETAILED DESCRIPTION

In general, according to one embodiment, a static field adjustment apparatus includes a plurality of holding members that hold a magnetic member for adjusting a distribution of a static magnetic field to be used in magnetic resonance imaging. All or some of the holding members are stacked in an axial direction and/or a radial direction of a magnet that has an annular shape and generates the static magnetic field, in a first space on an internal diameter side of the magnet.

### First Embodiment

In the description below, a static field adjustment apparatus and a magnetic resonance imaging system according to the present embodiment will be explained in detail, with reference to the drawings.

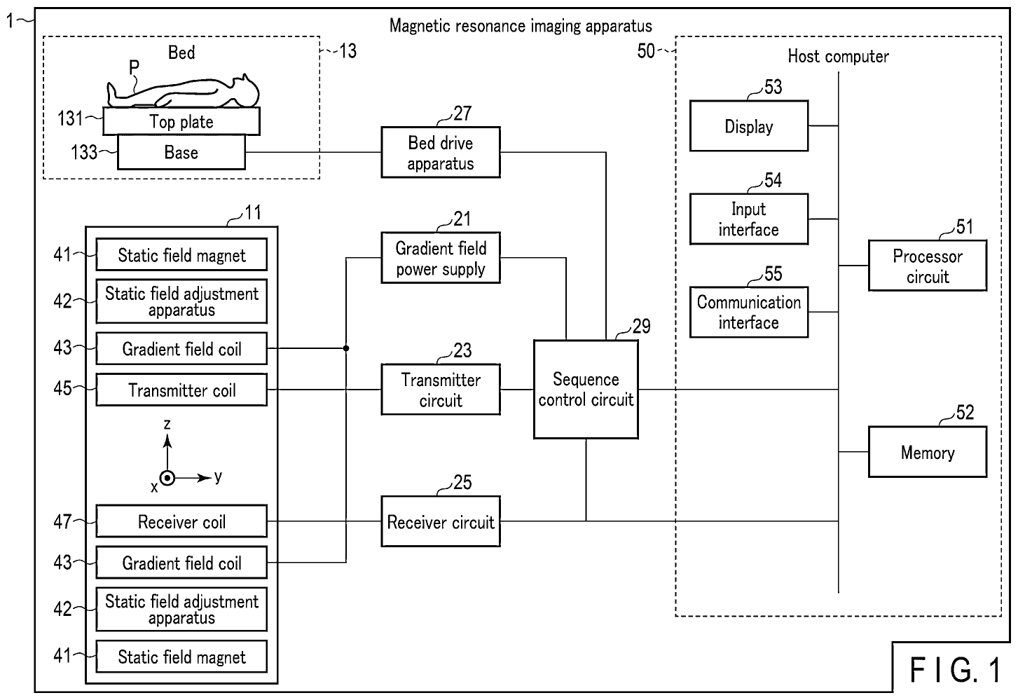

FIG. 1 is a diagram showing an example structure of a magnetic resonance imaging system 1 according to the present embodiment. As shown in FIG. 1, the magnetic resonance imaging system 1 includes a gantry 11, a bed 13, a gradient field power supply 21, a transmitter circuit 23, a receiver circuit 25, a bed drive apparatus 27, a sequence control circuit 29, and a host computer 50.

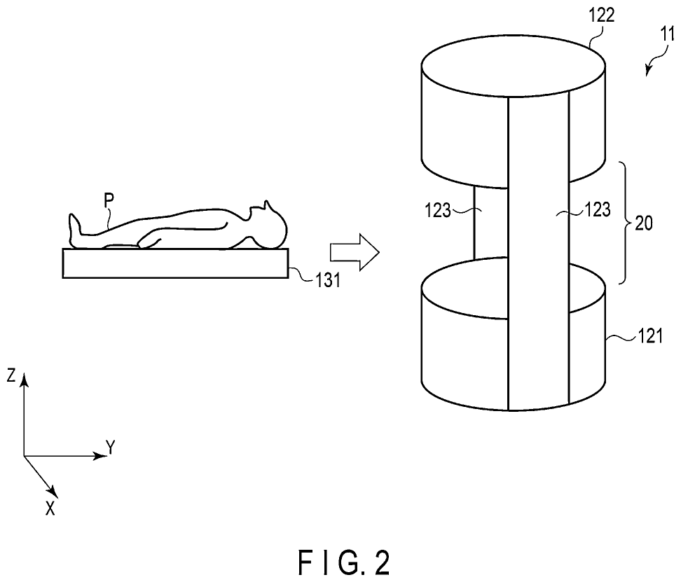

FIG. 2 is a perspective view of the gantry 11 according to the present embodiment. As shown in FIG. 2, the gantry 11 includes a lower housing 121 and an upper housing 122. The lower housing 121 is placed on the floor. The lower housing 121 and the upper housing 122 are connected by a pair of connecting members 123, with a space 20 being left in between. The form of support between the lower housing 121 and the upper housing 122 by the connecting members 123 is not limited to the support of both of the lower housing 121 and the upper housing 122 by the pair of connecting members 123 as shown in FIG. 2, but may be cantilever support by one of the connecting members 123.

A static field magnet 41, a static field adjustment apparatus 42, and a gradient field coil 43 are accommodated in each of the lower housing 121 and the upper housing 122. The static field magnet 41 is a magnet that has an annular shape and generates a static magnetic field to be used in magnetic resonance imaging. As the static field magnet 41, a permanent magnet, an electromagnet, a superconducting magnet, or a combination of two or more kinds of these magnets is used, for example. Here, the central axis of the static field magnet 41 is defined as the Z-axis, the axis that is horizontally orthogonal to the Z-axis and is parallel to the body axis of the subject P is defined as the Y-axis, and the axis orthogonal to the Y-axis and the Z-axis is defined as the X-axis.

The static field adjustment apparatus 42 is an instrument for adjusting a spatial distribution of the static magnetic field used in magnetic resonance imaging. Specifically, the static field adjustment apparatus 42 includes a plurality of holding members that hold the magnetic members for adjusting the distribution of the static magnetic field to be used in magnetic resonance imaging. All or some of the plurality of holding members are stacked in the Z-axis direction of the static field magnet 41 in a first space on the internal diameter side of the annular static field magnet 41 that generates a static magnetic field. In a case where some of the plurality of holding members are disposed in the first space, the remaining ones of the holding members may be stacked in the Z-axis direction of the static field magnet 41 in a second space other than the first space in the radial direction of the static field magnet 41.

The gradient field coil 43 generates a gradient field, receiving a supply of a current from the gradient field power supply 21. As an example, the gradient field coil 43 has three coils corresponding to the X-axis, the Y-axis, and the Z-axis orthogonal to one another. The three coils form a gradient field in which the magnetic field intensity changes along each of the X-axis, the Y-axis, and the Z-axis. The gradient field power supply 21 supplies a current to the gradient field coil 43 in accordance with a sequence control signal from the sequence control circuit 29. By supplying a current to the gradient field coil 43, the gradient field power supply 21 causes the gradient field coil 43 to generate a gradient field along each of the X-axis, the Y-axis, and the Z-axis. The gradient field is superimposed on the static magnetic field formed by the static field magnet 41, and is applied to the subject P.

Other than the above, a transmitter coil 45 and a receiver coil 47 are disposed on the gantry 11. The transmitter coil 45 is disposed between the lower housing 121 and the upper housing 122, for example, and generates a radio-frequency pulse (hereinafter referred to as an RF pulse) by receiving a current supply from the transmitter circuit 23. The transmitter circuit 23 supplies the current to the transmitter coil 45, to apply an RF pulse for exciting the target protons present in the subject P, to the subject P via the transmitter coil 45. The RF pulse oscillates at a resonance frequency unique to the target protons, to excite the target protons. An MR signal is generated from the excited target protons, and are detected by the receiver coil 47.

The receiver coil 47 is disposed between the lower housing 121 and the upper housing 122, for example, and receives the MR signal generated from the target protons present in the subject P, under the action of the RF pulse. The receiver coil 47 includes a plurality of receiver coil elements capable of receiving an MR signal. The received MR signal is supplied to the receiver circuit 25 in a wired or wireless manner. The receiver circuit 25 receives the MR signal generated from the excited target protons via the receiver coil 47. The receiver circuit 25 performs signal processing on the received MR signal, to generate a digital MR signal. The digital MR signal can be expressed in a k-space defined by the spatial frequency. Hereinafter, the digital MR signal will be referred to as k-space data. The k-space data is digital data expressing the signal strength value of the MR signal in a time function. The k-space data is supplied to the host computer 50 in a wired or wireless manner.

The transmitter coil 45 and the receiver coil 47 described above are merely an example. Instead of the transmitter coil 45 and the receiver coil 47, a transmitter/receiver coil having a transmission function and a reception function may be used. Also, the transmitter coil 45, the receiver coil 47, and the transmitter/receiver coil may be combined.

The bed 13 is installed adjacent to the gantry 11. The bed 13 includes a top plate 131 and a base 133. The subject P is placed on the top plate 131. The base 133 supports the top plate 131 so as to be slidable along each of the X-axis, the Y-axis, and the Z-axis. The bed drive apparatus 27 is accommodated in the base 133. The bed drive apparatus 27 moves the top plate 131, under the control of the sequence control circuit 29. The bed drive apparatus 27 may include any motor such as a servo motor or a stepping motor, for example.

The sequence control circuit 29 has, as hardware resources, a processor such as a central processing unit (CPU) or a micro processing unit (MPU), and a memory such as a read only memory (ROM) or a random access memory (RAM). The sequence control circuit 29 executes a predetermined pulse sequence by synchronously controlling the gradient field power supply 21, the transmitter circuit 23, and the receiver circuit 25, on the basis of a data collection condition that has been set by a processor circuit 51, and collects the MR signal emitted from the subject P. The receiver circuit 25 receives the MR signal via the receiver coil 47, and processes the received MR signal, to collect the k-space data.

As shown in FIG. 1, the host computer 50 is a computer that includes the processor circuit 51, a memory 52, a display 53, an input interface 54, and a communication interface 55. Data communication among the processor circuit 51, the memory 52, the display 53, the input interface 54, and the communication interface 55 is performed via a bus.

The processor circuit 51 includes a processor such as a CPU as a hardware resource. The processor circuit 51 functions as the center of the magnetic resonance imaging system 1. For example, the processor circuit 51 sets the data collection condition, designs a pulse sequence, reconstructs an MR image based on k-space data, performs image processing on an MR image, displays an MR image, and performs other processing, by executing various programs. Also, the processor circuit 51 may execute static field adjustment software for adjusting the static magnetic field distribution, to determine the material, the shape, the size, the number, and/or the like of the magnetic members mounted on the static field adjustment apparatus 42.

The memory 52 is a storage device such as a hard disk drive (HDD), a solid state drive (SSD), or an integrated circuit storage device that stores various kinds of information. Alternatively, the memory 52 may be a drive device or the like that reads and writes various kinds of information from and into a portable storage medium such as a CD-ROM drive, a DVD drive, or a flash memory.

The display 53 displays various kinds of information, under the control of the processor circuit 51. As the display 53, a CRT display, a liquid crystal display, an organic EL display, an LED display, a plasma display, or any other display known in the art can be used as appropriate, for example.

The input interface 54 includes an input device that accepts various instructions from the user. As the input device, a keyboard and mouse, various switches, a touch screen, a touch pad, or the like can be used. Note that the input device is not necessarily a device equipped with physical operation components such as a mouse and a keyboard. For example, an electric signal processing circuit that receives an electric signal corresponding to an input operation from an external input device provided separately from the magnetic resonance imaging system 1, and outputs the received electric signal to various circuits is also included among examples of the input interface 54. Also, the input interface 54 may be a voice recognition device that converts a voice signal collected by a microphone into a command signal.

The communication interface 55 is an interface that connects the magnetic resonance imaging system 1 to a workstation, a picture archiving and communication system (PACS), a hospital information system (HIS), a radiology information system (RIS), or the like via a local area network (LAN) or the like. The communication interface 55 transmits and receives various kinds of information to and from the workstation, the PACS, the HIS, and the RIS that are connection destinations.

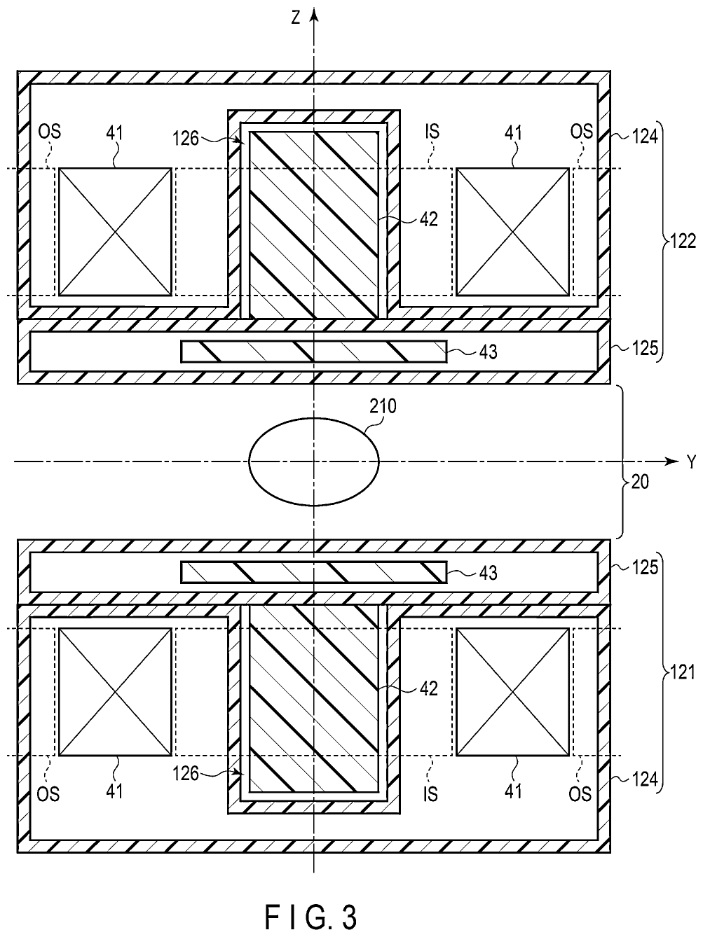

FIG. 3 is a schematic view of a Y-Z cross section of the gantry 11 shown in FIG. 2. As shown in FIG. 3, the lower housing 121 and the upper housing 122 are arranged, with the space 20 being left in between. The lower housing 121 and the upper housing 122 have substantially symmetrical internal structures with respect to the Y-axis. In the description below, to avoid repeated explanation, only the lower housing 121 will be explained regarding the components common to the lower housing 121 and the upper housing 122.

The lower housing 121 includes a first container 124 and a second container 125. The first container 124 is a vacuum container having a non-penetrating hollow portion 126. The cylindrical static field magnet 41 is accommodated in the first container 124. The static field magnet 41 is accommodated in the first container 124 so that the central axis of the first container 124 coincides with the central axis (Z-axis) of the static field magnet 41. As the static field magnet 41, one or a plurality of annular superconducting coils is used. In addition to the static field magnet 41, a refrigerant for maintaining a superconducting state of the static field magnet 41 is accommodated in the first container 124. As the refrigerant, liquid helium is used, for example. Note that, if a superconducting state can be maintained without any refrigerant, the refrigerant may not be included. Here, the space on the radially inner side of the static field magnet 41 is referred to as the internal diameter space IS, and the space on the radially outer side of the static field magnet 41 is referred to as the external diameter space OS. The internal diameter space IS is an example of the first space described above. The external diameter space OS is an example of the second space described above. In the present embodiment, an imaging space (field of view (FOV)) 210 is formed in the internal diameter space IS and the space 20 at a position deviating from the external diameter space OS. As an example, the imaging space 210 is formed in a local region intersecting with the Z-axis in the space 20.

The static field adjustment apparatus 42 is disposed in the hollow portion 126 of the first container 124, which is the internal diameter space IS of the static field magnet 41. The static field adjustment apparatus 42 adjusts the spatial distribution of the static magnetic field generated by the static field magnet 41, to enhance the uniformity of the spatial distribution in the imaging space 210. In other words, the static field adjustment apparatus 42 is disposed at a position where the uniformity of the static magnetic field distribution in the imaging space 210 can be enhanced. In the present embodiment, it is assumed that the imaging space 210 is located in a local area intersecting with the Z-axis. Therefore, the static field adjustment apparatus 42 is disposed in the internal diameter space IS, to enhance the uniformity of the static magnetic field distribution in the imaging space 210 located at the position.

As shown in FIG. 3, the second container 125 is disposed between the first container 124 and the space 20. The second container 125 accommodates the gradient field coil 43. The gradient field coil 43 superimposes a gradient field on the imaging space 210. The gradient field coil 43 is disposed at a position deviating from the internal diameter space IS and the external diameter space OS of the static field magnet 41. Note that the first container 124 and the second container 125 may be formed separately, or may be formed integrally.

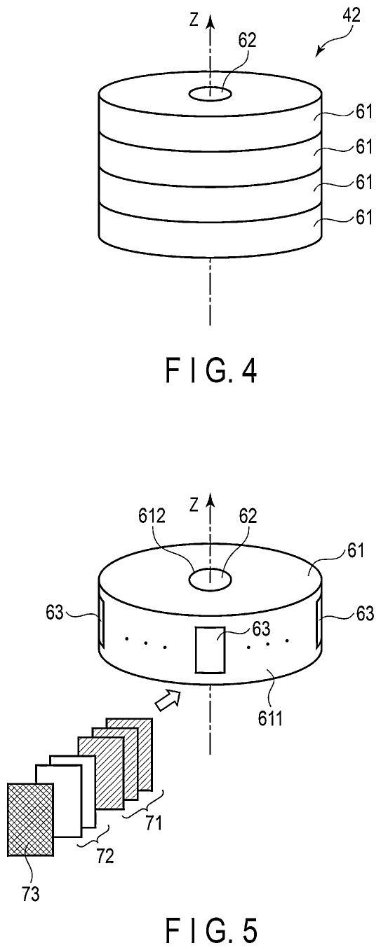

Next, the structure of the static field adjustment apparatus 42 is described. FIG. 4 is a perspective view of one mode of the static field adjustment apparatus 42. As shown in FIG. 4, the static field adjustment apparatus 42 includes a plurality of holding members 61 stacked along the Z-axis. The holding members 61 are structures that have an annular shape with a hollow portion 62, and are formed with a nonmetallic material such as a synthetic resin having no or minor influence on the static magnetic field distribution.

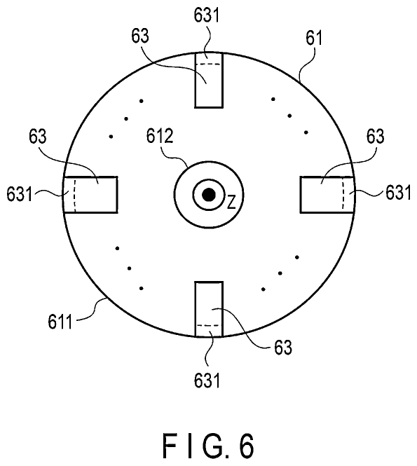

FIG. 5 is a perspective view of one mode of a holding member 61. FIG. 6 is a plan view of the holding member 61 shown in FIG. 5. As shown in FIGS. 5 and 6, the holding member 61 includes a plurality of accommodating portions 63 capable of accommodating magnetic members 71. The accommodating portions 63 are spaces communicating with openings 631 formed in the surface of the holding member 61, and are non-penetrating spaces that do not penetrate to an inner peripheral surface 612 of the holding member 61. As an example, the openings 631 are formed in an outer peripheral surface 611 of the holding member 61.

The magnetic members 71 for adjusting the spatial distribution of the static magnetic field are accommodated in the accommodating portions 63. The size and/or the shape of the accommodating portions 63 formed on the outer peripheral surface 611 can be designed as desired, depending on the size and/or the shape of the magnetic members 71 to be accommodated. The number and/or the positions of the accommodating portions 63 may be designed as desired, in accordance with the degree of freedom of adjustment of the spatial distribution of the static magnetic field by the magnetic members 71. Note that it is not necessary to provide the accommodating portions 63 in all of the holding members 61, and the accommodating portions 63 may be provided only in some of the holding members 61. The type of the magnetic members 71 can be selected as appropriate from among ferromagnetic substances such as silicon steel plates, electromagnetic steel plates, iron, nickel, ferrite, magnets, electromagnetic soft iron, permalloy, amorphous, permendur, and nanocrystals, soft magnetic materials, and the like. The shape of the magnetic members 71 can be selected as appropriate from among a quadrangle, a rectangle, a cylinder, a sphere, a triangle, a polygonal column, an annular shape, a tubular shape, and the like. The shape of the accommodating portions 63 may be designed in accordance with the shape of the magnetic members so that the magnetic members 71 can be accommodated.

In addition to the magnetic members 71, spacers 72 can be accommodated in the accommodating portions 63. The spacers 72 are structures that are used for adjusting and/or fixing the positions of the magnetic members 71 in the accommodating portions 63. The shape of the spacers 72 can be selected as appropriate from among a quadrangle, a rectangle, a cylinder, a sphere, an ellipse, a triangle, a polygonal column, an annular shape, a tubular shape, and the like. Typically, the spacers 72 may be selected as appropriate from among materials such as synthetic resins having less influence on the static magnetic field distribution.

The material, the shape, the size, and/or the number of the magnetic members 71 and/or the spacers 72 can be determined by a static magnetic field simulation that is performed by the processor circuit 51 using software for static magnetic field adjustment. In the static magnetic field simulation, the processor circuit 51 predicts the static magnetic field distribution based on static magnetic field information inside and outside the imaging space, superconducting coil information, magnetic member electromagnetic force information, magnetic member magnetic susceptibility information, gradient field information for static magnetic field correction, a magnetic field distribution method depending on the RF coil to be adopted, and/or pulse sequence/reconfiguration information to be used, and determines the material, the shape, the size, and/or the number of the magnetic members 71 and/or the spacers 72 so that the spatial uniformity of the static magnetic field distribution in the imaging space meets a predetermined standard.

As shown in FIG. 5, a lid 73 for closing the openings 631 of the accommodating portions 63 may be attached to the holding member 61. For example, the lid 73 is detachably attached to the holding member 61 with a fastener such as a screw or adhesive tape. Note that the mounting form of the lid 73 is not limited to the above, but may be attached to the holding member 61 so as to be openable and closable by a hinge or the like, or may be provided so as to be movable along the outer peripheral surface 611 by a linear motion guide or the like.

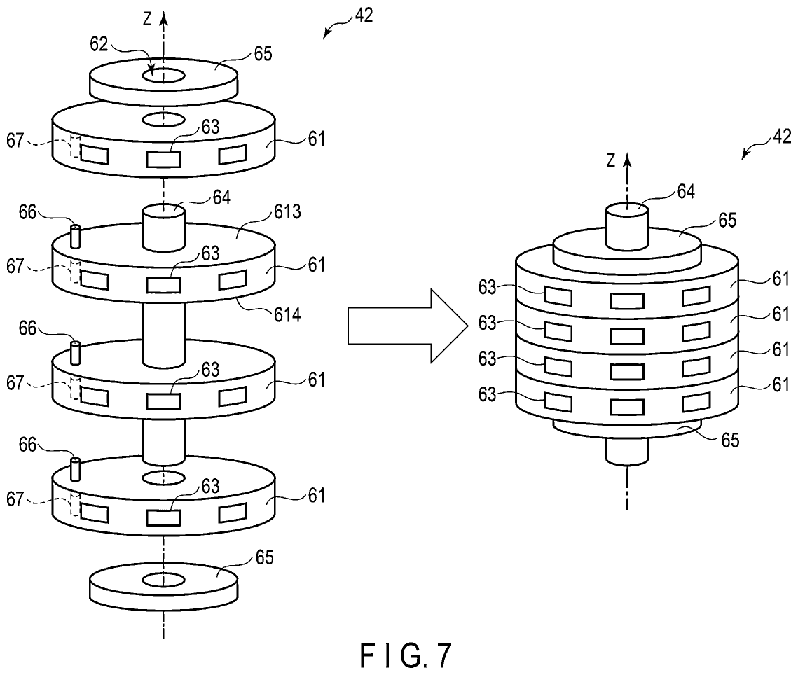

Next, the support of the plurality of holding members 61 in the Z-axis direction is described with reference to FIG. 7. FIG. 7 is a view of an example of the support of the plurality of holding members 61 by support members 64, 65, 66, and 67. The left-side drawing in FIG. 7 is a perspective view of the static field adjustment apparatus 42 before being fixed by the support members 64, 65, 66, and 67, and the right-side drawing is a perspective view of the static field adjustment apparatus 42 after being fixed by the support members 64, 65, 66, and 67. As an example, the static field adjustment apparatus 42 in FIG. 7 holds four holding members 61. However, the number of holding members 61 held by the static field adjustment apparatus 42 is not limited to this, and the number is not limited as long as the number is two or larger.

As shown in the left-side drawing in FIG. 7, the static field adjustment apparatus 42 includes the support members 64, 65, 66, and 67 that support the plurality of holding members 61 so that the holding members 61 can be stacked in the Z-axis direction. As described above, each of the holding members 61 has an annular shape having the hollow portion 62 formed therein. As an example of the support member, a fixing rod 64 inserted through the hollow portions 62 of the plurality of holding members 61 is used. By penetrating the plurality of holding members 61 with the fixing rod 64, it is possible to suppress changes in the positions of the holding member 61 in a direction orthogonal to the Z-axis. To suppress rotation and the like of the holding members 61 with respect to the fixing rod 64, key grooves, which are protrusions and grooves to be structurally fitted to the protrusions, may be formed in part of the outer peripheral surfaces of the holding members 61 and part of the side peripheral surface of the fixing rod 64 corresponding to the parts. This makes it possible to ensure correction of the static magnetic field by the magnetic members.

As shown in FIG. 7, the holding members 61 at both ends with respect to the Z-axis of the plurality of holding members 61 having the fixing rod 64 inserted therethrough are fixed to the fixing rod 64 by a pair of fastening tools 65. The pair of fastening tools 65 is mechanically detachably fixed to the fixing rod 64 after sandwiching the plurality of holding members 61 from the two sides in the Z-axis direction. For example, the fastening tools 65 and the fixing rod 64 can be fixed by fastener members such as screws or pins, or by key groove processing. This makes it possible to ensure correction of the static magnetic field by the magnetic members.

The fixing rod 64 may have an accommodating portion (not shown in FIG. 7) into which a magnetic sensor can be inserted. The magnetic sensor detects a magnetic field distribution in at least one of the X-, Y-, and Z-axis directions. An electric signal (a magnetic field detection signal) indicating the strength of the magnetic field detected by the magnetic sensor is supplied to the processor circuit 51, and may be used in a static magnetic field simulation or the like. Note that the magnetic sensor may be provided on the holding member 61, instead of the fixing rod 64. In this case, the magnetic sensor may be accommodated in the accommodating portion 63 or some other space, or may be attached to the surface of the holding member 61.

As shown in FIG. 7, as a support member, each of the holding members 61 has a protrusion 66 on a top surface 613 orthogonal to the Z-axis direction, and a recess 67 that can be fitted to the protrusion 66 on a bottom surface 614 on the side opposite to the top surface 613. That is, each of the holding members 61 has the protrusion 66 for connecting to another holding member 61 in contact with the top surface 613, and the recess 67 for connecting to another holding member 61 in contact with the bottom surface 614. In other words, key groove processing is performed on each holding member 61. By the key groove processing, it is possible to suppress relative rotation of each holding member 61 with respect to the other holding members 61.

Here, the sequence for assembling the static field adjustment apparatus 42 is briefly described. First, magnetic members are accommodated in the respective accommodating portions 63 of each of the holding members 61. Note that magnetic members do not need to be accommodated in all the accommodating portions 63. Likewise, any magnetic member may not be accommodated in some of the holding members 61. Next, the fixing rod 64 is inserted through the hollow portions 62 of the plurality of holding members 61, and the plurality of holding members 61 are fixed with the pair of fastening tools 65. Thus, the assembly of the static field adjustment apparatus 42 is completed.

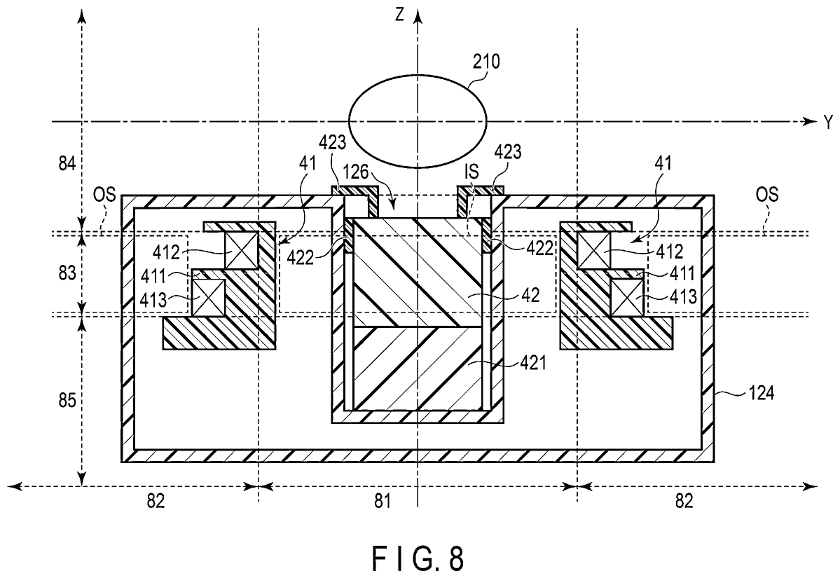

Next, a positional relationship between the static field magnet 41 and the static field adjustment apparatus 42 is described. FIG. 8 is a drawing showing a Y-Z cross section of the first container 124 shown in FIG. 3. As shown in FIG. 8, the static field magnet 41 is accommodated in the first container 124. The static field magnet 41 includes a support base 411, a first superconducting coil 412, and a second superconducting coil 413. The support base 411 is a support structure for the first superconducting coil 412 and the second superconducting coil 413.

The first superconducting coil 412 and the second superconducting coil 413 are annular superconducting coils having different diameters from each other. The first superconducting coil 412 and the second superconducting coil 413 are disposed so that the central axes thereof coincide with the Z-axis. The first superconducting coil 412 and the second superconducting coil 413 are disposed so that radial directions thereof are parallel to the Y-axis direction. The first superconducting coil 412 is located closer to the side of the imaging space 210 than the second superconducting coil 413, and has the smaller diameter. Note that the positions of the first superconducting coil 412 and the second superconducting coil 413 may be reversed. Further, the number of superconducting coils included in the static field magnet 41 is not limited to two, but may be three or larger.

Here, the region on the inner side the first superconducting coil 412 and the second superconducting coil 413 in the Y-axis direction is referred to as the internal diameter region 81. Specifically, the minimum diameter formed by the first superconducting coil 412 and the second superconducting coil 413, which is the inner side of the minimum diameter of the first superconducting coil 412, is the internal diameter region 81. The region on the outer side the internal diameter region 81 in the Y-axis direction is referred to as the external diameter region 82. Also, the region occupied by the first superconducting coil 412 and the second superconducting coil 413 in the Z-axis direction is referred to as the coil region 83, the region closer to the imaging space 210 than the coil region 83 is referred to as the upper region 84, and the region closer to the floor than the coil region 83 is referred to as the lower region 85. The area in which the internal diameter region 81 and the coil region 83 overlap is defined in the internal diameter space IS. More specifically, the region that overlaps the internal diameter region 81 and the coil region 83, and is on the inner side of the support base 411 is defined in the internal diameter space IS. The area in which the external diameter region 82 and the coil region 83 overlap is defined in the external diameter space OS.

As currents are supplied to the first superconducting coil 412 and the second superconducting coil 413, a static magnetic field is generated from the first superconducting coil 412 and the second superconducting coil 413. By supplying currents of mutually independent strengths and/or phases to the first superconducting coil 412 and the second superconducting coil 413, the imaging space 210 having static magnetic field uniformity that can be used in magnetic resonance imaging is formed in the area on the outer side of the internal diameter space IS, or more specifically, in the area in which the internal diameter region 81 and the upper region 84 overlap.

As shown in FIG. 8, the first container 124 and the static field magnet 41 are arranged so that the internal diameter space IS is located in the hollow portion 126 formed in the first container 124. All or some of the holding members included in the static field adjustment apparatus 42 are disposed in the hollow portion 126 that is the internal diameter space IS and is formed by the first container 124. All or some of the holding members included in the static field adjustment apparatus 42 are disposed, with a tool being interposed between the bottom surface and/or the inner wall surface of the first container 124 in contact with the hollow portion 126, the tool being for adjusting the positions of all or some of the holding members.

Specifically, as shown in FIG. 8, since the static field adjustment apparatus 42 is disposed in the internal diameter space IS, the static field adjustment apparatus 42 is raised from the bottom surface of the non-penetrating hollow portion 126 via a spacer 421. The spacer 421 is a support structure that is formed with a nonmetallic material such as a synthetic resin having no or minor influence on the static magnetic field distribution. Note that the region in which the static field adjustment apparatus 42 exists may extend outside the internal diameter space IS. As shown in FIG. 8, to fill the gap between the hollow portion 126 and the static field adjustment apparatus 42 in the radial direction of the hollow portion 126, a holding member 422 is inserted between the inner wall surface of the hollow portion 126 and the static field adjustment apparatus 42. By inserting the holding member 422, it is possible to suppress a change in the position of the static field adjustment apparatus 42 in the hollow portion 126. Further, to fix the static field adjustment apparatus 42 to the first container 124, another holding member 423 may be provided in part of the opening at the upper portion of the hollow portion 126 in the Z-axis direction. The holding member 423 can push the static field adjustment apparatus 42 from above. The holding member 423 may be provided so as to cover the entire opening at the upper portion of the hollow portion 126 in the Z-axis direction.

As the holding members that hold the magnetic members are made stackable in the Z-axis direction as described above, it is possible to hold the shimming magnetic members with a high degree of freedom even in a case where a cylindrical MRI in which bores are formed is not used. Thus, the position and/or the shape of the imaging space with a static magnetic field distribution of high uniformity can be designed with a high degree of freedom, except for the inner space of the annular static field magnet.

The above embodiment is an example, and various elements can be deleted, added, and/or changed.

### Modification 1 of the First Embodiment

The accommodating portions according to the above embodiment are provided on the outer peripheral surfaces of the holding members. However, the present embodiment is not limited to this. The accommodating portions may be provided on the outer peripheral surfaces, the inner peripheral surfaces, the top surfaces, and/or the bottom surfaces of the holding members.

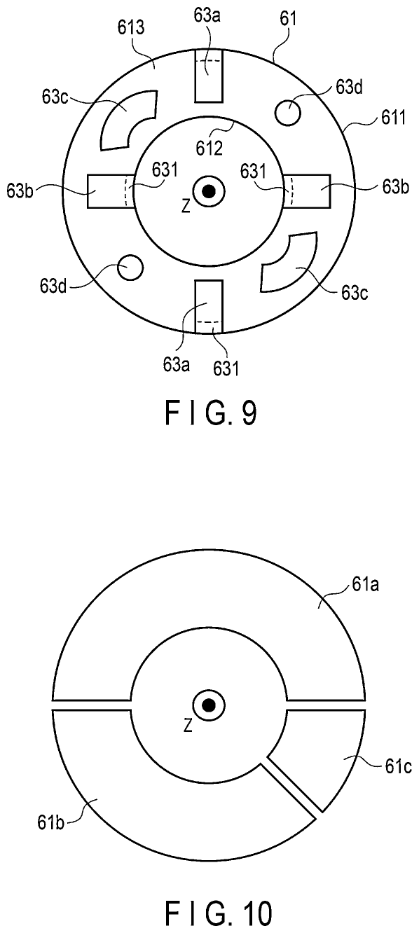

FIG. 9 is a plan view of a holding member 61 according to Modification 1 of the first embodiment. As shown in FIG. 9, accommodating portions 63a are provided on the outer peripheral surface 611 of the holding member 61, as in the above-described embodiment. Other than that, accommodating portions 63b may be provided on the inner peripheral surface 612 of the holding member 61. The accommodating portions 63b are non-penetrating spaces that have openings 631 on the inner peripheral surface 612, and accommodate magnetic members. Further, accommodating portions 63c and 63d may be provided on the top surface 613 of the holding member 61. The accommodating portions 63c and the accommodating portions 63d are non-penetrating spaces that have openings on the top surface 613, and accommodate magnetic members. The accommodating portions 63c and the accommodating portions 63d have different shapes. The accommodating portions 63c may have an arc-like shape in a plane, the accommodating portions 63d may have a circular shape, or any other shapes as long as the magnetic members can be accommodated therein.

According to Modification 1 of the first embodiment, the accommodating portions 63 in which the magnetic members are accommodated may be formed on any surface of the holding member 61. As a result, it is possible to form the holding member 61 on any desired surface, taking into account the easiness of access to the accommodating portions 63 by an operator.

### Modification 2 of the First Embodiment

The holding members according to the above embodiment have an annular shape. However, the present embodiment is not limited to this. Holding members may have any shape as long as magnetic members can be accommodated therein.

FIG. 10 is a plan view of holding members 61a, 61b, and 61c according to Modification 2 of the first embodiment. As shown in FIG. 10, the holding members 61a, 61b, and 61c have an arc-like shape. The respective shapes of the holding members 61a, 61b, and 61c may be designed to have an annular shape when the holding members 61a, 61b, and 61c are combined. The holding members 61a, 61b, and 61c are preferably fixed to one another by key groove processing or the like, to suppress mutual positional displacement. Note that the shapes of the holding members 61a, 61b, and 61c are not limited to an annular shape and an arc-like shape, but may be any shape such as a polygonal shape, a spherical shape, or a linear shape.

### Modification 3 of the First Embodiment

The holding members according to the above embodiment has a single-layer structure in a radial direction. However, the present embodiment is not limited to this. All or some of a plurality of holding members according to Modification 3 of the first embodiment have a multilayer structure in a radial direction. Specifically, all or some of the holding members according to Modification 3 of the first embodiment each include a plurality of holder layers arranged in a radial direction orthogonal to the Z-axis direction, and each of the holder layers can hold a magnetic member. In the description below, a holding member according to Modification 3 of the first embodiment is explained.

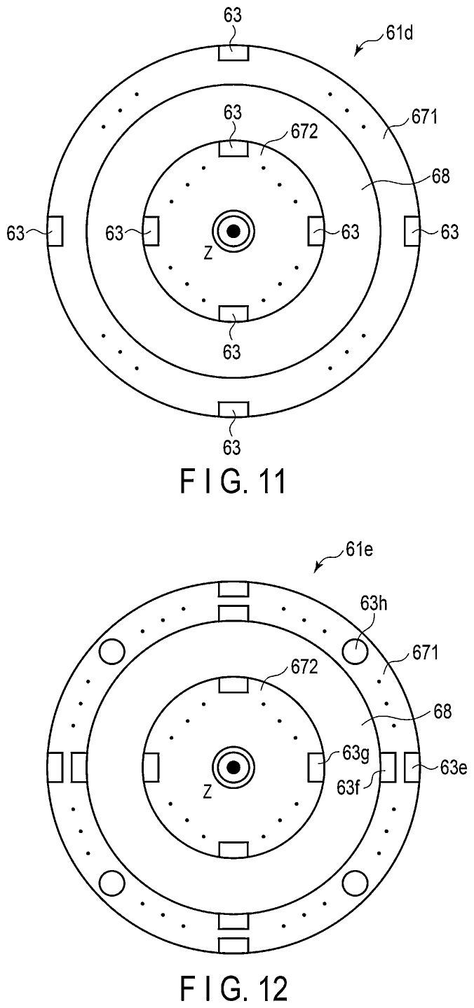

FIG. 11 is a drawing showing a plan view of a holding member 61d according to Modification 3 of the first embodiment. As shown in FIG. 11, the holding member 61d includes a plurality of holder layers 671 and 672 arranged in the radial direction. Each of the holder layers 671 and 672 has one or a plurality of accommodating portions 63 in which magnetic members are accommodated. The position, the shape, and/or the number of the accommodating portions 63 can be designed as appropriate by static field correction software or the like as in the above embodiment. The number of the holder layers 671 and 672 is not limited to any particular number, as long as the number is two or larger. In the following description, however, it is assumed that the number of holder layers is two, which are the first holder layer 671 and the second holder layer 672.

As shown in FIG. 11, in Modification 3 of the first embodiment, the accommodating portions 63 are provided on the outer peripheral surface side of each of the first holder layer 671 and the second holder layer 672. A spacer layer 68 is provided between the first holder layer 671 and the second holder layer 672. The spacer layer 68 is provided to fix the positions of the first holder layer 671 and the second holder layer 672. The first holder layer 671, the spacer layer 68, and the second holder layer 672 may be provided with a fixing means such as key-groove processing so as to be fixed to one another. Note that, if the positions of the holder layers can be fixed to each other, the spacer layer 68 may not be provided.

The sequence for assembling the holding member 61d according to Modification 3 of the first embodiment is now briefly described. First, magnetic members are accommodated in the first holder layer 671 and the second holder layer 672. Next, a fixing rod (not shown in FIG. 11) is inserted into the second holder layer 672, which is the innermost layer, and the second holder layer 672 and the fixing rod are fixed to each other. Next, the spacer layer 68 is fitted into the second holder layer 672, and the first holder layer 671 is fitted into the spacer layer 68. Thus, the assembly of the holding member 61d according to Modification 3 of the first embodiment is completed.

According to Modification 3 of the first embodiment, all or some of the holding members each have a multilayer structure in a radial direction. Accordingly, the degree of freedom of arrangement of the magnetic members in the radial direction is increased, and thus, the static magnetic field can be adjusted with precision.

### Modification 4 of the First Embodiment

In the above Modification 3 of the first embodiment, the first holder layer disposed on the outermost periphery has the accommodating portions on the outer peripheral surface. However, the present embodiment is not limited to this. The holder layers other than the holder layer on the innermost periphery among a plurality of holder layers according to Modification 4 of the first embodiment each include a first accommodating portion having an opening in its outer peripheral surface, a second accommodating portion having an opening in its inner peripheral surface, a third accommodating portion having an opening in its top surface, and/or a fourth accommodating portion having an opening in its bottom surface, to hold magnetic members. In the description below, a static field adjustment apparatus according to Modification 4 of the first embodiment is explained.

FIG. 12 is a drawing showing a plan view of a holding member 61e according to Modification 4 of the first embodiment. As shown in FIG. 12, the holding member 61e includes a plurality of holder layers 671 and 672 arranged in a radial direction. Each of the holder layers 671 and 672 has one or a plurality of accommodating portions 63e, 63f, 63g, and 63h in which magnetic members are accommodated. The position, the shape, and/or the number of the accommodating portions 63 can be designed as appropriate by static field correction software or the like as in the above embodiment. The number of the holder layers is not limited to any particular number, as long as the number is two or larger. In the following description, however, it is assumed that the number of holder layers is two, which are the first holder layer 671 and the second holder layer 672.

As shown in FIG. 12, the first holder layer 671 has accommodating portions 63f provided on its inner peripheral surface and accommodating portions 63h provided on its top surface, in addition to accommodating portions 63e provided on its outer peripheral surface. The second holder layer 672 has accommodating portions 63g provided on the outer peripheral surface. A magnetic member or a spacer can be disposed as appropriate in each of the accommodating portions 63e, 63f, 63g, and 63h.

Note that the accommodating portions 63e provided on the outer peripheral surface and the accommodating portions 63h provided on the top surface may not be provided, and the accommodating portions 63f may be provided only on the inner peripheral surface. Providing the accommodating portions 63f on the inner peripheral surface is expected to enhance workability. Other than on the first holder layer 671 as the outermost layer, accommodating portions may be provided on the inner peripheral surface, the top surface, and/or the bottom surface in addition to the outer peripheral surface of the second holder layer 672 as the innermost layer and other holder layers.

According to Modification 4 of the first embodiment, accommodating portions can be provided on any surface of each holder layer, and thus, accessibility to the accommodating portions is enhanced.

### Modification 5 of the First Embodiment

In the embodiment described above, the static field adjustment apparatus includes the support member that supports a plurality of holding members stacked in the Z-axis direction. However, the present embodiment is not limited to this. Support members according to Modification 5 of the first embodiment may support spacers for adjusting the spaces among the plurality of holding members in a stackable manner.

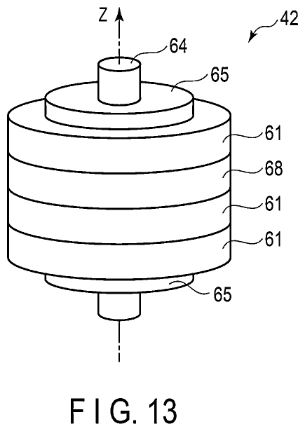

FIG. 13 is a perspective view of one mode of a static field adjustment apparatus 42 according to Modification 5 of the first embodiment. Like the static field adjustment apparatus 42 shown in FIG. 7 and others, the static field adjustment apparatus 42 shown in FIG. 13 has a four-stage structure. As shown in FIG. 13, annular holding members 61 and a spacer layer 68 are stacked in the Z-axis direction, a fixing rod 64 is inserted through the hollow portion of each of the holding members 61 and the spacer layer 68, and the holding members 61 and the spacer layer 68 are fixed by fastening tools 65. The spacer layer 68 is provided to create a space between two adjacent holding members 61 in the Z-axis direction. Like the holding members 61, the spacer layer 68 may be provided with a fixing means such as key groove processing for fixing its position with respect to an adjacent holding member 61, or a fixing means such as key groove processing for fixing the position with respect to the fixing rod 64.

Although the spacer layer 68 is disposed between the holding member 61 in the uppermost stage and the holding member 61 in the second stage in FIG. 13, the installation position of the spacer layer 68 is not limited to this. Further, although only one spacer layer 68 is disposed between the holding member 61 in the uppermost stage and the holding member 61 in the second stage in FIG. 13, two, three, or a larger number of spacer layers 68 may be provided as necessary. The position, the number, and/or the thickness in the Z-axis direction of the spacer layer 68 can be designed as appropriate by static field correction software.

According to Modification 5 of the first embodiment, a spacer layer can be provided between holding members. Accordingly, the degree of freedom of arrangement of magnetic members is increased, and thus, adjustment of the static magnetic field can be performed with higher precision.

### Modification 6 of the First Embodiment

The first housing according to the embodiment described above has the hollow portion (hereinafter a non-penetrating hollow portion) 126 that does not penetrate in the Z-axis direction. However, the present embodiment is not limited to this. A first housing according to Modification 6 of the first embodiment may have a hollow portion (hereinafter a penetrating hollow portion) that penetrates in the Z-axis direction. In this case, a static field adjustment apparatus is disposed in the penetrating hollow portion. To fix the position of the static field adjustment apparatus in the penetrating hollow portion, the static field adjustment apparatus is preferably fixed to the first housing via an appropriate holding member. As an example, the holding member may be provided so as to support the static field adjustment apparatus from the bottom surface side of the penetrating hollow portion.

### Modification 7 of the First Embodiment

In the above embodiment, the static field adjustment apparatus 42 is disposed in the internal diameter space IS of the static field magnet 41 as shown in FIG. 8 and others. However, the present embodiment is not limited to this. All of a plurality of holding members according to Modification 7 of the first embodiment are disposed in an external diameter space OS outside a static field magnet 41, the external diameter space OS being located outside a first housing and a second housing that accommodate the static field magnet. In the description below, a static field adjustment apparatus according to Modification 7 of the first embodiment is explained.

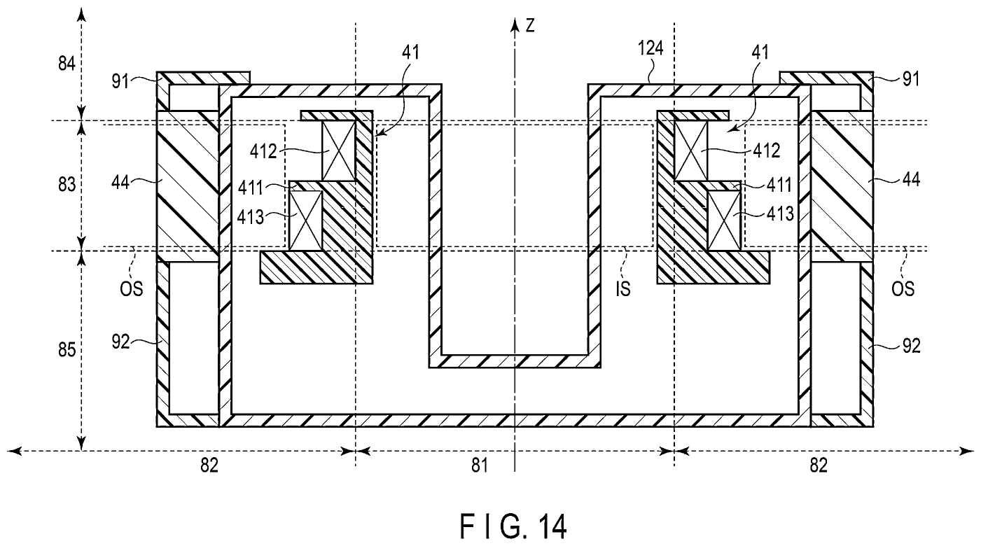

FIG. 14 is a drawing showing a Y-Z cross section of a first container 124 according to Modification 7 of the first embodiment. As shown in FIG. 14, a static field adjustment apparatus 44 according to Modification 7 of the first embodiment has a cylindrical shape with a hollow portion, and is disposed in the external diameter space OS so as to surround the outer periphery of the first container 124. The first container 124 is disposed in the hollow portion of the static field adjustment apparatus 44. Like the above static field adjustment apparatus 42, the static field adjustment apparatus 44 includes a plurality of annular holding members stacked in the Z-axis direction. To prevent positional deviation of holding members from each other, key groove processing with the protrusion 66, the recess 67, and the like shown in FIG. 7 may be performed on the top surface and the bottom surface of each holding member.

As shown in FIG. 14, the static field adjustment apparatus 44 is disposed in a coil region 83 in the Z-axis direction. To be disposed in the coil region 83, the static field adjustment apparatus 44 is held in the first container 124 via holding members 91 and 92. Specifically, the holding member 92 holds the static field adjustment apparatus 44, to raise the height of the static field adjustment apparatus 44 from the floor to the coil region 83. The holding member 91 fixes the static field adjustment apparatus 44 to the first container 124. In a case where the static field adjustment apparatus 44 can be fixed only by the holding member 92, the holding member 91 may not be provided. Note that, to fix the static field adjustment apparatus 44 and the first container 124 to each other, a fixing means such as key groove processing may be performed on both the static field adjustment apparatus 44 and the first container 124.

According to Modification 7 of the first embodiment, the static field adjustment apparatus 44 is disposed in the external diameter space OS, and thus, an area with a uniform static magnetic field distribution can be provided in an external diameter region 82 in an upper region 84. Note that the external diameter space OS in which the static field adjustment apparatus 44 is disposed is not limited only to the above example. As an example, in a case where another housing that accommodates a cryostat or a correction coil exists in a space on the outer peripheral side of the first container 124, a non-penetrating hollow portion or a penetrating hollow portion may be provided in the another housing, and the static field adjustment apparatus 44 may be disposed in the non-penetrating hollow portion or the penetrating hollow portion. As another example, a non-penetrating hollow portion or a penetrating hollow portion may be provided on the outer periphery of the another housing, and the static field adjustment apparatus 44 may be disposed in the non-penetrating hollow portion or the penetrating hollow portion. The portion in which the static field adjustment apparatus 44 is disposed is also an example of the external diameter space OS or the second space.

### Modification 8 of the First Embodiment

All of the holding members according to the above embodiment are provided in one of the internal diameter area and the external diameter area of the static field magnet. However, the present embodiment is not limited to this. A plurality of holding members according to Modification 8 is provided in both the internal diameter area and the external diameter area of the static field magnet. In the description below, a static field adjustment apparatus according to Modification 8 of the first embodiment is explained.

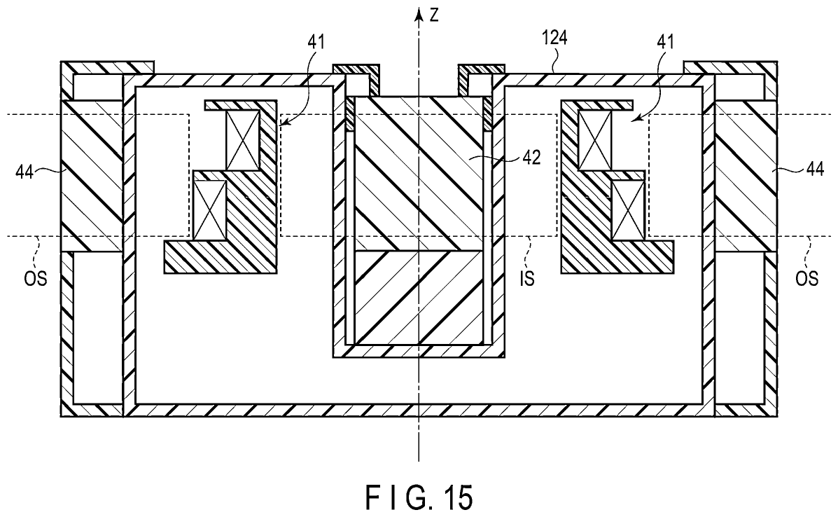

FIG. 15 is a drawing showing a Y-Z cross section of a first container 124 according to Modification 8 of the first embodiment. As shown in FIG. 15, a static field adjustment apparatus 42 is provided in an internal diameter space IS, and a static field adjustment apparatus 44 is provided in an external diameter space OS. That is, holding members that accommodate magnetic members are disposed in both the internal diameter space IS and the external diameter space OS. According to Modification 8 of the first embodiment, the space in which the magnetic members can be disposed can be widened. As a result, an imaging space 210 is expected to be expanded.

### Modification 9 of the First Embodiment

In the first embodiment described above, the static field adjustment apparatus 42 is provided in the hollow portion 126 of each of the lower housing 121 and the upper housing 122 shown in FIG. 3. However, the present embodiment is not limited to this. The static field adjustment apparatus 42 may be provided only in the hollow portion 126 of one of the lower housing 121 and the upper housing 122. Also, the static field adjustment apparatus 42 can be adopted not only in the magnetic resonance imaging system 1 having both the lower housing 121 and the upper housing 122, but also in a magnetic resonance imaging system having only one of the lower housing 121 and the upper housing 122.

### Second Embodiment

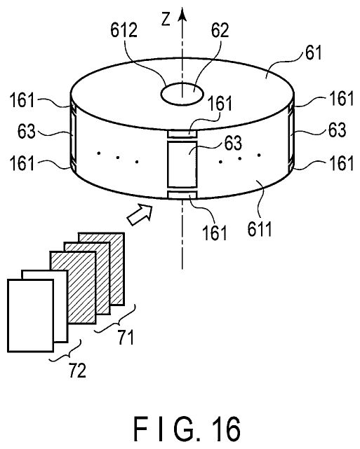

FIG. 16 is a perspective view of one mode of a holding member 61 according to a second embodiment. As shown in FIG. 16, the holding member 61 includes a plurality of accommodating portions 63 capable of accommodating shimming magnetic members 71. The accommodating portions 63 are spaces communicating with openings formed in the surface of the holding member 61. As an example, the accommodating portions 63 each have an opening in the outer peripheral surface 611 of the holding member 61, and forms a non-penetrating space that does not reach the inner peripheral surface 612 of the holding member 61.

The shimming magnetic members 71 for adjusting the spatial distribution of the static magnetic field are accommodated in the accommodating portions 63. The size and/or the shape of the accommodating portions 63 formed on the outer peripheral surface 611 can be designed as desired, depending on the size and/or the shape of the magnetic members 71 to be accommodated. The number and/or the positions of the accommodating portions 63 may be designed as desired, in accordance with the degree of freedom of adjustment of the spatial distribution of the static magnetic field by the magnetic members 71. Note that it is not necessary to provide the accommodating portions 63 in all of the holding members 61, and the accommodating portions 63 may be provided only in some of the holding members 61. The type of the magnetic members 71 can be selected as appropriate from among ferromagnetic substances such as silicon steel plates, electromagnetic steel plates, iron, nickel, ferrite, magnets, electromagnetic soft iron, permalloy, amorphous, permendur, and nanocrystals, soft magnetic materials, and the like. The shape of the magnetic members 71 can be selected as appropriate from among a quadrangle, a rectangle, a cylinder, a sphere, an ellipse, a triangle, a polygonal column, an annular shape, a tubular shape, and the like.

In addition to the magnetic members 71, spacers 72 can be accommodated in the accommodating portions 63. The spacers 72 are structures that are used for adjusting and/or fixing the positions of the magnetic members 71 in the accommodating portions 63. The shape of the spacers 72 can be selected as appropriate from among a quadrangle, a rectangle, a cylinder, a sphere, a triangle, a polygonal column, an annular shape, a tubular shape, and the like. Typically, the spacers 72 may be selected as appropriate from among materials such as synthetic resins having less influence on the static magnetic field distribution.

The material, the shape, the size, and/or the number of the magnetic members 71 and/or the spacers 72 can be determined by a static magnetic field simulation that is performed by the processor circuit 51 using software for static magnetic field adjustment. In the static magnetic field simulation, the processor circuit 51 predicts the static magnetic field distribution based on static magnetic field information inside and outside the imaging space, superconducting coil information, magnetic member electromagnetic force information, magnetic member magnetic susceptibility information, gradient field information for static magnetic field correction, a magnetic field distribution method depending on the RF coil to be adopted, and/or pulse sequence/reconfiguration information to be used, and determines the material, the shape, the size, and/or the number of the magnetic members 71 and/or the spacers 72 so that the spatial uniformity of the static magnetic field distribution in the imaging space meets a predetermined standard.

As shown in FIG. 16, the holding member 61 is provided with fastening tools 161 for attaching a later-described lid portion (not shown in FIG. 16) to the holding member 61. The fastening tools 161 are typically provided for each of the accommodating portions 63. As an example, the fastening tools 161 are provided in the vicinity of the upper side and the vicinity of the lower side of each of the accommodating portions 63. As another example, the fastening tools 161 may be provided only in the vicinity of one of the upper side and the lower side. Note that the positions of the fastening tools 161 are not limited to the positions shown in FIG. 16, but may be provided so as to surround each accommodating portion 63, or may be provided near the left side and/or the right side. The fastening tools 161 will be described later in detail.

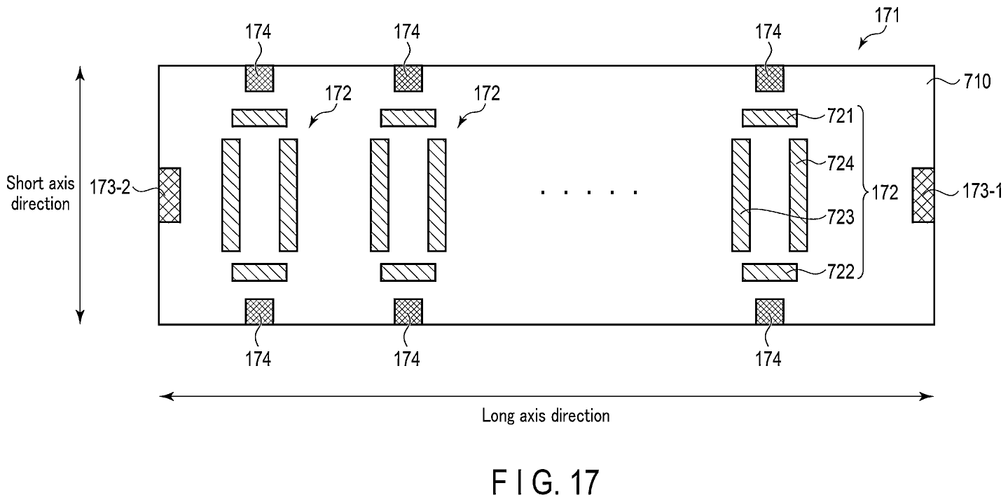

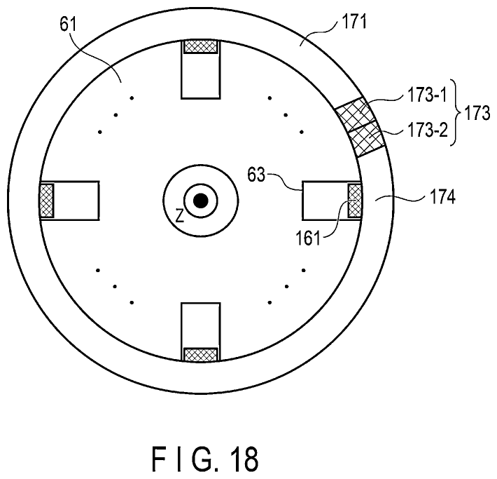

FIG. 17 is a developed view of the inner peripheral surface side of a lid portion 171. FIG. 18 is a plan view of a holding member 61 around which the lid portion 171 is wound (this holding member will be hereinafter referred to as a lidded holding member). The “inner peripheral surface” of the lid portion 171 means the surface facing the outer peripheral surface 611 of the holding member 61. The “short axis direction” of the lid portion 171 corresponds to the Z-axis direction of the holding member 61, and the “long axis direction” of the lid portion 171 corresponds to the circumferential direction of the holding member 61.

As shown in FIGS. 17 and 18, the lid portion 171 has a film member 710 that has flexibility and is in the form of film. The shape of the film member 710 may be selected from among a quadrangle, an ellipse, a circle, an arc, a curve, a bent line, a cylinder, a sphere, a triangular prism, a polygonal prism, an annular shape, a tubular shape, and any appropriate shape (free form), in addition to the rectangle shown as an example in FIG. 17 and others, in accordance with the shape of the magnetic members and the shape of the holding member 61. The material of the film member 710 may be selected from among materials having hardness of such a degree that the material can be made to extend along the outer peripheral surface of the holding member 61. For example, soft PVC, urethane, rubber, synthetic resin, or the like may be used as the film member 710. On the inner peripheral surface of the lid portion 171, two or more fixing tools 172 for fixing the magnetic members 71 accommodated in two or more accommodating portions 63 to be covered among the accommodating portions 63 of the holding member 61 are provided at two or more positions respectively corresponding to the two or more accommodating portions 63 to be covered. In the example in FIGS. 17 and 18, it is assumed that the accommodating portions 63 to be covered are all the accommodating portions 63 formed in the holding member 61. The pitch of the fixing tools 172 in the long axis direction and the pitch of the accommodating portions 63 in the circumferential direction are designed to have substantially the same values.

As each of the two or more fixing tools 172, a spacer to be inserted into an accommodating portion 63 is used. As the fixing tools 172 are inserted into the accommodating portions 63, the magnetic members 71 accommodated in the accommodating portions 63 and the spacers 72 are held down and fixed by the fixing tools 172. The fixing tools 172 each include a plurality of frame members 721, 722, 723, and 724 that are arranged so as to be insertable into the accommodating portions 63. The frame members 721, 722, 723, and 724 are stick-like structures that are formed with a nonmetallic material such as a synthetic resin having no or minor influence on the static magnetic field distribution. The frame members 721, 722, 723, and 724 are arranged, with a gap being left between each two. As the gaps are left, the degree of close contact between the lid portion 171 and the holding member 61 can be increased when the lid portion 171 is wound around the holding member 61. The frame members 721, 722, 723, and 724 are fixed to the film member 710 by an appropriate fixing means such as a tightening tool such as a screw or tape, an adhesive, or key groove processing.

The structure of the frame members 721, 722, 723, and 724 may be designed depending on the shape of the openings of the accommodating portion 63. For example, in a case where the shape of the openings of the accommodating portion 63 is rectangular, a frame member is formed with an upper horizontal frame 721, a lower horizontal frame 722, a left vertical frame 723, and a right vertical frame 724, and the upper horizontal frame 721, the lower horizontal frame 722, the left vertical frame 723, and the right vertical frame 724 are arranged in a rectangular shape so as to be inscribed in an opening of the accommodating portion 63.

Each of the frame members 721, 722, 723, and 724 has the shape of a prism. Each of the frame members 721, 722, 723, and 724 has a predetermined thickness in the depth direction of the accommodating portion 63. The frame members are stacked in the depth direction of the accommodating portion 63, depending on the total thickness of the magnetic members 71 accommodated in the accommodating portion 63. Specifically, when the lid portion 171 is wound around the holding member 61, the frame members 721, 722, 723, and 724 are stacked in the depth direction to such an extent that the frame members 721, 722, 723, and 724 come into contact with the magnetic members 71 and the spacers 72 accommodated in the accommodating portions 63. This makes it possible to hold down and fix the magnetic members 71 and the spacers 72 accommodated in the accommodating portions 63. The stacked frame members 721, 722, 723, and 724 may be fixed to one another by fastening tools such as screws or tape, an adhesive, or key groove processing. Note that the shape of the frame members 721, 722, 723, and 724 is not limited to a prismatic shape, but may have any shape as long as the frame members can be stacked. Alternatively, the frame members 721, 722, 723, and 724 may be designed to be stretchable in the thickness direction.

The lid portion 171 shown in FIGS. 17 and 18 is formed so as to be able to cover all of the plurality of accommodating portions 63 formed in the holding member 61. In this case, the long axis direction of the film member 710 has such a length that the film member 710 can be wound around the outer peripheral surface of the holding member 61. A pair of lid fastening tools 173-1 and 173-2 to be detachably joined to each other are provided at both ends of the film member 710 in the long axis direction. The lid fastening tools 173-1 and 173-2 may include an appropriate fixing means such as a screw, a button, a hook and loop fastener, a protrusion, or a groove. With this arrangement, both ends of the film member 710 in the long axis direction can be fixed to the holding member 61. Since the film member 710 has such a length that the film member 710 can be wound around the outer peripheral surface of the holding member 61, the lid portion 171 can cover all the accommodating portions 63 on the outer peripheral surface of the holding member 61 with one sheet.

The holding member 61 and the lid portion 171 have a pair of holding fastening tools 161 and 174 to be detachably joined to each other. For example, the holding fastening tool 161 on the side of the holding member 61 has a claw, and the holding fastening tool 174 on the side of the lid portion 171 has a groove to be engaged with the claw. The pitch of the holding fastening tools 174 in the long axis direction in the lid portion 171 and the pitch of the holding fastening tools 161 in the circumferential direction in the holding member 61 are designed to have substantially the same values. The holding fastening tools 174 are preferably provided in the vicinity of the fixing tools 172, to enhance adhesion between the holding member 61 and the lid portion 171 around the accommodating portions 63.

Here, the sequence for assembling the holding member 61 around which the lid portion 171 is wound is described. First, magnetic members are accommodated in the accommodating portions 63 of the holding member 61. Note that magnetic members do not need to be accommodated in all the accommodating portions 63. Next, the lid portion 171 is wound around the holding member 61. Specifically, each fixing tool 172 is inserted into each corresponding accommodating portion 63, the holding fastening tools 161 and 174 are attached to each other, the lid portion 171 is wound around the holding member 61, and lastly, the lid fastening tools 173-1 and 173-2 are attached to each other. Thus, the assembly of the holding member 61 around which the lid portion 171 is wound is completed.

As described above, a holding member including accommodating portions for accommodating magnetic members is covered with a lid portion, so that the accommodating portions are closed with the lid portion. Thus, an operation of closing accommodating portions with a lid can be easily performed, compared with that in a conventional example in which accommodating portions are closed one by one.

The above embodiment is an example, and various elements can be deleted, added, and/or changed.

### Modification 1 of the Second Embodiment

In the above embodiment, a lid portion covers the entire circumference of a holding member. However, the present embodiment is not limited to this. A lid portion according to Modification 1 of the second embodiment covers only part of the outer peripheral surface of a holding member. In the description below, a static field adjustment apparatus according to Modification 1 is explained.

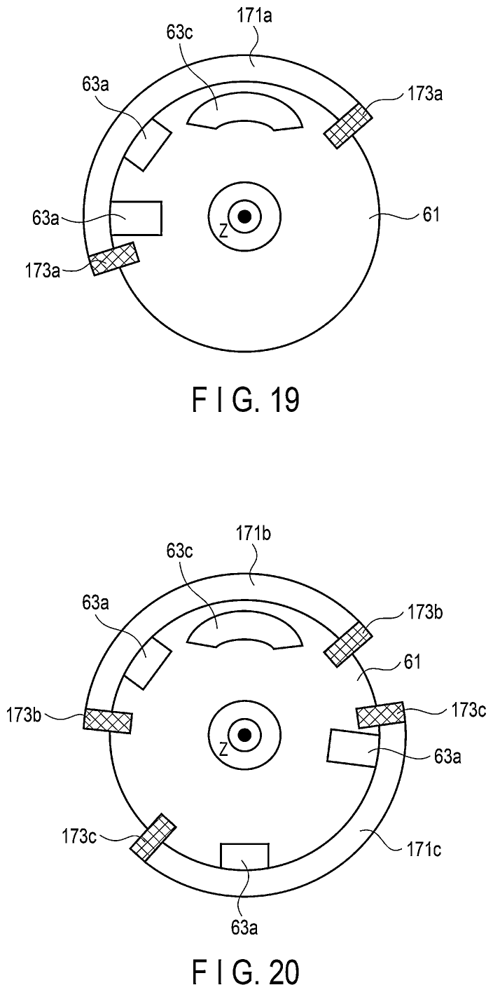

FIG. 19 is a plan view of a lidded holding member 61 according to Modification 1 of the second embodiment. As shown in FIG. 19, the holding member 61 according to Modification 1 of the second embodiment includes a plurality of accommodating portions 63a locally provided on the outer peripheral surface. A magnetic member is accommodated in each of the accommodating portions 63a. Like the lid portion 171 shown in FIG. 17, a lid portion 171a according to Modification 1 has fixing tools 172 and holding fastening tools 174 on the inner peripheral surface. The length of the lid portion 171a in the long axis direction is designed to be sufficient to cover all of the plurality of accommodating portions 63a to be covered with one sheet. Lid fastening tools 173a are provided at both ends of the lid portion 171a in the long axis direction. The lid fastening tools 173a are designed to be attachable to the holding member 61. With the lid fastening tools 173a, the lid portion 171a can be attached to the holding member 61.

Note that the holding member 61 may also have accommodating portions 63c on the top surface. The shape of the accommodating portions 63c is not limited to the arc-like shape shown in FIG. 19, but can be designed to be any appropriate shape such as a rectangular shape, a linear shape, or a circular shape. It is assumed that the accommodating portions 63c are covered with a means separate from the lid portion 171a.

### Modification 2 of the Second Embodiment

In the above embodiment, a lid portion covers all of a plurality of accommodating portions provided on the outer peripheral surface of a holding member, with one sheet. However, the present embodiment is not limited to this. A lid portion according to Modification 2 of the second embodiment covers only some of the accommodating portions provided on the outer peripheral surface of a holding member. In the description below, a static field adjustment apparatus according to Modification 2 of the second embodiment is explained.

FIG. 20 is a plan view of a lidded holding member 61 according to Modification 2 of the second embodiment. As shown in FIG. 20, the holding member 61 according to Modification 2 of the second embodiment includes a plurality of accommodating portions 63a provided on the outer peripheral surface. A magnetic member is accommodated in each of the accommodating portions 63a. The plurality of accommodating portions 63a is provided over the entire outer peripheral surface of the holding member 61.

As shown in FIG. 20, a plurality of lid portions is prepared in Modification 2 of the second embodiment. Although the number of the lid portions may be any number that is two or larger, FIG. 20 shows an example in which two lid portions 171b and 171c are prepared. All of the plurality of accommodating portions 63a provided on the outer peripheral surface of the holding member 61 are covered with the two lid portions 171b and 171c. Like the lid portion 171 shown in FIG. 17, the lid portions 171b and 171c have fixing tools 172 and holding fastening tools 174 on the inner peripheral surface. The length of each of the lid portions 171b and 171c according to Modification 2 is designed to be sufficient to cover the accommodating portions 63a to be covered by the lid portions 171b and 171c. For example, there are two accommodating portions 63a to be covered, and therefore, the lid portion 171c is only required to have a length sufficient to cover all of the two accommodating portions 63a with one sheet. Lid fastening tools 173b and 173c are provided at both ends of the lid portions 171b and 171c in the long axis direction. The lid fastening tools 173b and 173c are designed to be attachable to the holding member 61. With the lid fastening tools 173b and 173c, the lid portions 171b and 171c can be attached to the holding member 61.

### Modification 3 of the Second Embodiment

The holding members in the above embodiment have an annular shape. However, the present embodiment is not limited to this. Holding members may have the shape of a polygon. The polygon may have any number of sides, like a triangle, a pentagon, or a hexagon. In the description below, a static field adjustment apparatus according to Modification 3 of the second embodiment is explained.

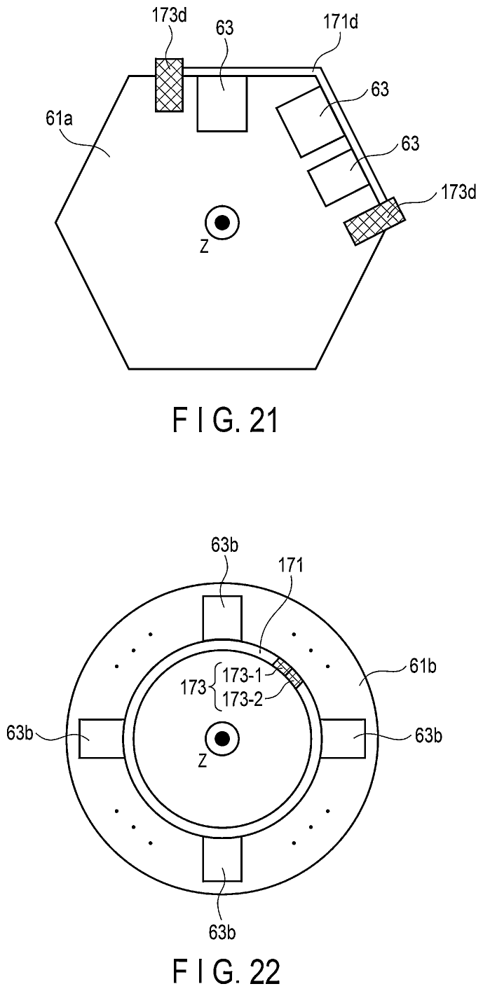

FIG. 21 is a plan view of a lidded holding member 61a according to Modification 3 of the second embodiment. As shown in FIG. 21, the holding member 61a according to Modification 3 of the second embodiment has a hexagonal shape. A plurality of accommodating portions 63 is locally provided on the outer peripheral surface of the holding member 61a. Like the lid portion 171 shown in FIG. 17, a lid portion 171d according to Modification 3 of the second embodiment has fixing tools 172 and holding fastening tools 174 on the inner peripheral surface. The length of the lid portion 171d in the long axis direction is designed to be sufficient to cover all of the plurality of accommodating portions 63 with one sheet. Lid fastening tools 173d are provided at both ends of the lid portion 171d in the long axis direction. The lid fastening tools 173d are designed to be attachable to the holding member 61a. With the lid fastening tools 173d, the lid portion 171d can be attached to the holding member 61a.

Note that, in a case where the holding member has a polygonal shape, accommodating portions may be provided over the entire outer peripheral surface. In this case, a single lid portion may cover all of the accommodating portions formed on the outer peripheral surface, or a plurality of lid portions may cover all of the accommodating portions.

### Modification 4 of the Second Embodiment

In the above embodiment, the accommodating portions are provided on the outer peripheral surfaces of the holding members. However, the present embodiment is not limited to this. Accommodating portions according to Modification 4 of the second embodiment are provided on the inner peripheral surface of each holding member. In this case, a lid portion is wound around the holding member so as to cover two or more accommodating portions that are to be covered and are provided on the inner peripheral surface of the holding member, with one sheet. In the description below, a static field adjustment apparatus according to Modification 4 of the second embodiment is explained.

FIG. 22 is a plan view of a lidded holding member 61b according to Modification 4 of the second embodiment. As shown in FIG. 22, the holding member 61b according to Modification 4 of the second embodiment includes a plurality of accommodating portions 63b provided over the entire inner peripheral surface. Each of the accommodating portions 63b is a space that communicates with an opening formed in the inner peripheral surface, and accommodates a magnetic member. The length of a lid portion 171 in the long axis direction is designed to be sufficient to cover all of the plurality of accommodating portions 63b with one sheet, or, in other words, to be sufficient to cover the inner peripheral surface of the holding member 61b. As shown in FIG. 17, the lid portion 171 has fixing tools 172 and holding fastening tools 174 on the inner peripheral surface. The fixing tools 172 are inserted into the accommodating portions 63b, to fix the magnetic members accommodated in the accommodating portions 63b. A pair of lid fastening tools 173 are provided at both ends of the lid portion 171 in the long axis direction, and the lid fastening tools 173 are attached to each other, so that both ends of the lid portion 171 in the long axis direction can be fixed to the holding member 61b. As the inner peripheral surface is covered with the lid portion 171, the plurality of accommodating portions 63b formed on the inner peripheral surface can be closed with the lid portion 171.

Note that the accommodating portions are not necessarily provided over the entire inner peripheral surface as in this example, but may be provided only locally. In this case, the lid portion 171 may have a length sufficient to cover the entire inner peripheral surface, or may have a length sufficient to cover the region in which the accommodating portions exist. All the accommodating portions 63b are not necessarily covered with the single lid portion 171 as in this example, but a plurality of lid portions 171 may cover all the accommodating portions 63b. The accommodating portions may be provided on both the outer peripheral surface and the inner peripheral surface of the holding member.

### Modification 5 of the Second Embodiment

The holding members in the above embodiment have an annular shape or a polygonal shape. However, the present embodiment is not limited to this. A holding member according to Modification 5 of the second embodiment has a plate-like shape. In the description below, a static field adjustment apparatus according to Modification 5 of the second embodiment is explained.

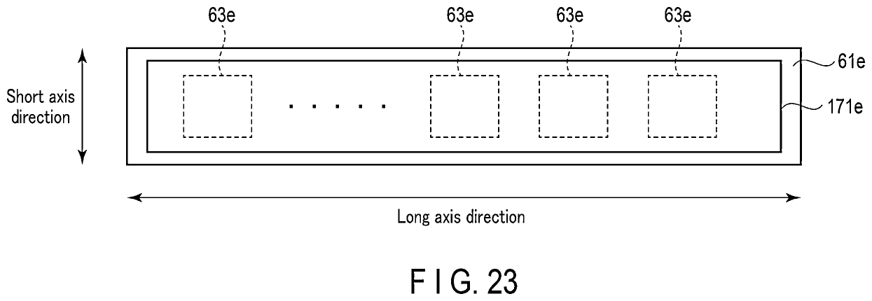

FIG. 23 is a plan view of a lidded holding member 61e according to Modification 5 of the second embodiment. As shown in FIG. 23, the holding member 61e according to Modification 5 of the second embodiment is a structure having a plate-like shape. A plurality of accommodating portions 63e arranged in a line in the long axis direction is formed on one principal surface of the holding member 61e. Magnetic members and spacers are accommodated in the respective accommodating portions 63e. It is assumed that the accommodating portions 63e have the same shape and the same size. Like the lid portion 171 shown in FIG. 17, a lid portion 171e according to Modification 5 has fixing tools 172 and holding fastening tools 174 on the inner peripheral surface. The length of the lid portion 171e in the long axis direction is designed to be sufficient to cover the accommodating portions 63e to be covered. As a principal surface of the holding member 61e is covered with the lid portion 171e, the plurality of accommodating portions 63e formed on the principal surface can be closed with the lid portion 171e.

The holding members 61e can also be stacked in the thickness direction of the plate-like shape (the depth direction on the drawing in FIG. 23). The plurality of stacked holding members 61e can be disposed in the hollow portion 126 of the first container 124 so that the thickness direction coincides with the Z-axis direction.

Note that the holding members 61e can also be adopted in a cylindrical MRI having bores. In this case, the holding members 61e plays a role similar to that of a shim tray. That is, the holding members 61e can be inserted into plate-shaped or rectangular spaces (hereinafter referred to as the accommodating spaces) that are formed in gaps between gradient field coils of a cylindrical gantry and extends in the axial direction of the cylindrical gantry. In this case, the holding members 61e are inserted into the accommodating spaces so that the long axis direction thereof extends in the axial direction of the cylindrical gantry.

### Modification 6 of the Second Embodiment

Modification 6 of the second embodiment is an example application of Modification 5 of the second embodiment. In the above Modification 5 of the second embodiment, the plurality of accommodating portions have the same shape and the same size, and are arranged in a line in the long axis direction. However, the present embodiment is not limited to this. A plurality of accommodating portions according to Modification 6 of the second embodiment can be arranged in any appropriate layout. In the description below, a static field adjustment apparatus according to Modification 6 of the second embodiment is explained.

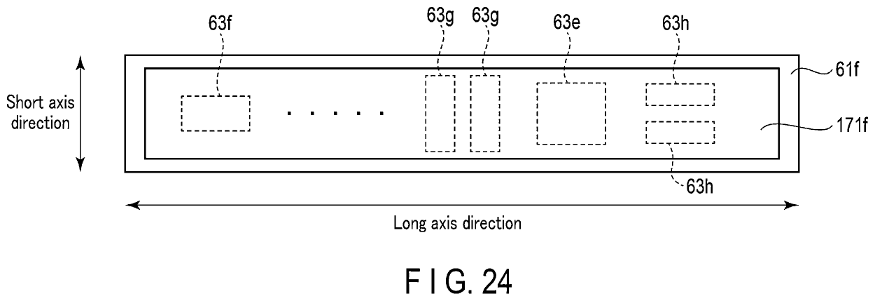

FIG. 24 is a plan view of a lidded holding member 61f according to Modification 6 of the second embodiment. As shown in FIG. 24, the holding member 61f according to Modification 6 of the second embodiment is a structure having a plate-like shape, like the holding members 61e according to Modification 5 of the second embodiment. Accommodating portions 63e, 63f, 63g, and 63h having a plurality of sizes and shapes are formed on one principal surface of the holding member 61f. Magnetic members and spacers are accommodated in the respective accommodating portions 63e, 63f, 63g, and 63h. By increasing the degree of freedom of the sizes, the shapes, and/or the arrangement of the accommodating portions 63e, 63f, 63g, and 63h, it is possible to enhance the uniformity of the static magnetic field.

Like the lid portion 171 shown in FIG. 17, a lid portion 171f according to Modification 6 of the second embodiment has fixing tools 172 and holding fastening tools 174 on the inner peripheral surface. The fixing tools 172 are provided at positions corresponding to the accommodating portions 63e, 63f, 63g, and 63h. This makes it possible to fix the magnetic members and the spacers accommodated in the respective accommodating portions 63e, 63f, 63g, and 63h. Also, the holding fastening tools 174 are provided at positions corresponding to the accommodating portions 63e, 63f, 63g, and 63h. Thus, the lid portion 171f and the holding member 61f can be fixed in close contact with each other. The length of the lid portion 171f in the long axis direction is designed to be sufficient to cover the accommodating portions 63e, 63f, 63g, and 63h to be covered. As a principal surface of the holding member 61f is covered with the lid portion 171f, the plurality of accommodating portions 63e, 63f, 63g, and 63h formed on the principal surface can be closed with the lid portion 171f.

### Modification 7 of the Second Embodiment

In the above second embodiment, the static field adjustment apparatus 42 is disposed in the internal diameter space IS of the static field magnet 41 as shown in FIG. 3 and others. However, the present embodiment is not limited to this. The static field adjustment apparatus 42 may be disposed in the external diameter space OS of the static field magnet 41, which is outside the lower housing 121 that accommodates the static field magnet 41. By disposing the static field adjustment apparatus 42 in the external diameter space OS, it is possible to change the position of the imaging space 210. Further, the static field adjustment apparatus 42 may be provided in both the internal diameter space IS and the external diameter space OS. Thus, the imaging space 210 can be expanded.

### Modification 8 of the Second Embodiment

In the second embodiment described above, the static field adjustment apparatus 42 is provided in the hollow portion 126 of each of the lower housing 121 and the upper housing 122 shown in FIG. 3. However, the present embodiment is not limited to this. The static field adjustment apparatus 42 may be provided only in the hollow portion 126 of one of the lower housing 121 and the upper housing 122. Also, the static field adjustment apparatus 42 can be adopted not only in the magnetic resonance imaging system 1 having both the lower housing 121 and the upper housing 122, but also in a magnetic resonance imaging system having only one of the lower housing 121 and the upper housing 122.

### Third Embodiment

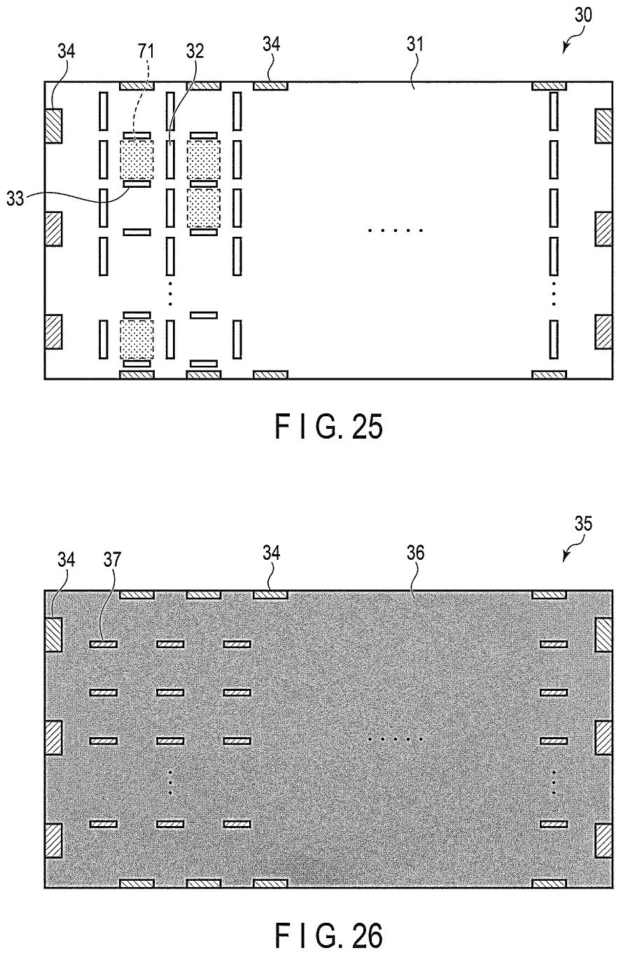

A first structural example of a static field adjustment apparatus for adjusting a static magnetic field generated by a superconducting magnet according to a third embodiment is described with reference to FIGS. 25 to 27.

The static field adjustment apparatus according to the first structural example is assumed to be formed with a two-layer sheet. FIG. 25 shows a first layer 30 of the static field adjustment apparatus according to the first structural example. In the first layer 30, a first sheet 31, first partition members 32 and 33, and fixing portions 34 are disposed.

The first sheet 31 is a planar sheet on which magnetic members are to be disposed, and is assumed to be formed with a flexible material herein. That is, the first sheet 31 has flexibility. For example, a flexible material such as soft PVC, urethane, or rubber, or a material having low rigidity is shaped in the form of a sheet.

The first partition members 32 and 33 are formed on the surface on which magnetic members 71 are disposed, and partition the areas in which the magnetic members 71 are to be disposed. The first partition members 32 and 33 are only required to be formed with a material having flexibility, for example. A material having plasticity or a material having high rigidity may be used, as long as there is no influence in a case where the material is wound. The first partition members 32 are rectangular partitions extending in the vertical direction in FIG. 25, and have a predetermined height from the first sheet 31. Likewise, the first partition members 33 are rectangular partitions extending in the horizontal direction in FIG. 25, and have a predetermined height from the first sheet 31. The first partition members 32 and 33 are arranged in a two-dimensional lattice, and the magnetic members 71 are disposed in the areas surrounded by the first partition members 32 and 33. The height of the first partition members 32 and 33 from the first sheet 31 may be designed as appropriate, depending on the maximum value of the height (the maximum value of the thickness) of the magnetic members 71 to be disposed.

The fixing portions 34 are member for fixing sheets to each other, or members to be used in a case where the static field adjustment apparatus 42 is fixed in a wound shape. As for the fixing portions 34, fixable members or a scheme, such as screws, pins, buttons, a hook and loop fastener, a scheme of engaging with a groove, or a scheme of engaging with a claw, may be used, for example.

The magnetic members 71 are magnetic members for adjusting a magnetic field, and may be formed with a ferromagnetic substance or a soft magnetic material, such as silicon steel plates, electromagnetic steel plates, iron, nickel, ferrite, magnets, electromagnetic soft iron, permalloy, amorphous, permendur, or nanocrystal, for example. It is assumed that the magnetic members 71 have a rectangular plate-like shape.

Note that guidelines indicating the positions in which the magnetic members 71 are to be disposed may be drawn on the first sheet 31.

FIG. 26 shows a second layer 35 of the static field adjustment apparatus 42. In the second layer 35, a second sheet 36, second partition members 37, and fixing portions 34 are disposed.

The second sheet 36 is a sheet formed with the same material as the first sheet. That is, the second sheet 36 is a planar sheet having flexibility.

The second partition members 37 are rectangular partitions extending in the horizontal direction in FIG. 26. The second partition members 37 are formed on the surface of the second layer 35 facing the surface of the first layer 30 on which the magnetic members are disposed. Also, in a case where the first layer 30 and the second layer 35 are stacked, the second partition members 37 are placed in the gaps between the first partition members 32 and 33, to surround the areas in which the magnetic members 71 are to be disposed. The second partition members 37 may also be formed with the same material as the first partition members 32 and 33.

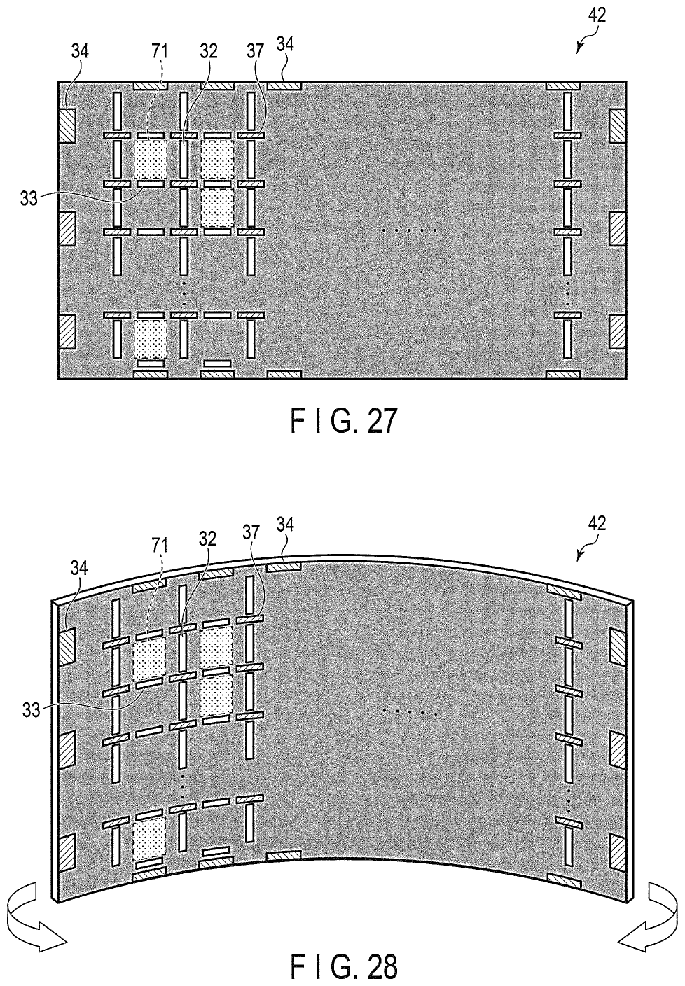

Next, the static field adjustment apparatus 42 in which the first layer 30 and the second layer 35 are stacked according to the first structural example is described with reference to FIG. 27.

FIG. 27 is a conceptual diagram showing a member layout between the layers in a case where the first layer 30 and the second layer 35 are stacked and fixed. Specifically, the layers are stacked so that the surface of the first layer 30 on which the magnetic members 71 and the first partition members 32 and 33 are disposed, and the surface of the second layer 35 on which the second partition members 37 are disposed face each other. The first layer 30 and the second layer 35 are fixed to each other by the fixing portions 34. For example, if the fixing portions 34 are screws, the first layer 30 and the second layer 35 are fixed to each other by screwing. Further, if the fixing portions 34 are of a scheme of engaging with claws, claws are formed as the fixing portions 34 of the first layer 30, receiving portions such as grooves are formed as the fixing portions 34 of the second layer, and the claws of the first layer 30 are fitted into the grooves of the second layer so that the layers are fixed to each other. Other than that, the layers may be fixed to each other with buttons, a hook and loop fastener, an adhesive, or the like. A state in which the first sheet 31 and the second sheet 36 are stacked is also referred to simply as a sheet.

Being interposed between the first layer 30 and the second layer 35, or in the sheet, the first partition members 32 and 33, the second partition members 37, and the magnetic members 71 are fixed. Thus, the static field adjustment apparatus 42 is formed. As shown in FIG. 27, the second partition members 37 are placed in the gaps between the first partition members 32 and 33 to form grid-like walls, and the areas in which the magnetic members 71 are disposed are partitioned by the walls.

Note that, in the areas in which the magnetic members 71 are disposed, spacers 72 such as rubber or resin for holding and fixing the magnetic members 71 in a case where the number of magnetic members 71 is small may be stored. Further, grooves or recesses for fixing the magnetic members 71 may be formed in the first partition members 32 and 33 and the second partition members 37.

Next, a conceptual diagram in a case where the static field adjustment apparatus 42 is rolled is shown in FIG. 28.

As shown in FIG. 28, the static field adjustment apparatus 42 can be rolled in a state where the first layer 30 and the second layer 35 are stacked. For example, the static field adjustment apparatus 42 is wound around a winding core which is a core member for winding, and the ends are fixed to each other by the fixing portions 34 provided at the ends in the winding direction, so that the static field adjustment apparatus 42 having a cylindrical shape can be formed. Of course, the fixing portions 34 are not necessarily used. Instead, the static field adjustment apparatus 42 may be wound around a winding core, and be then wound and fixed with another sheet, tape, or the like, starting from the outer periphery of the static field adjustment apparatus 42. Note that the static field adjustment apparatus 42 is not necessarily wound in a circle, but may have a shape curved in an arc-like shape such as a semicircular shape, or, in other words, in a semi-cylindrical shape.

As described above, the first partition members 32 and 33 and the second partition members 37 are formed in such a shape and a layout that adjacent members do not interfere with each other in a case where winding is performed in a state where the first layer 30 and the second layer 35 are stacked. That is, by disposing the second partition members 37 so as to fill the gaps between the first partition members 32 and 33 designed for rolling the first layer 30 in a cylindrical shape, it is possible to form grid-like walls for fixing and holding the magnetic members 71 in the cylindrical state.

Note that the first partition members 33 and the second partition members 37 may be formed in a tapered shape whose width increases in the direction from the surface of the first layer 30 toward the coaxial center of the winding core, depending on the curvature with which the winding around the winding core is performed. That is, the first partition members 33 and the second partition members 37 may be designed to be substantially in close contact with each other when the winding is performed.

Further, in the areas where the magnetic members 71 are not disposed, spacers 72 formed with resin, rubber, or the like may be disposed in place of the magnetic members 71. As a result, in a case where a magnetic field is applied to the static field adjustment apparatus 42, the shape may be changed by the magnetic force depending on the material of each partition member, and the thickness of the sheet might change, as the spaces in the areas where the magnetic members 71 are not disposed are crushed, for example. Therefore, the spacers 72 are provided, so that the thickness between the layers of the static field adjustment apparatus 42 can be kept constant.

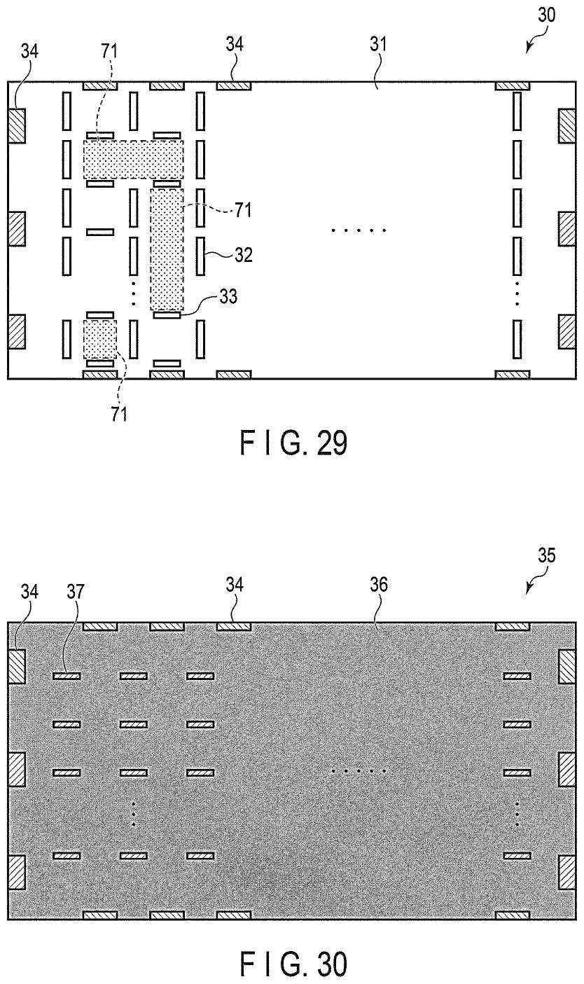

Next, a second structural example of the static field adjustment apparatus 42 is described with reference to FIGS. 29 to 31. First, the first layer 30 of the static field adjustment apparatus 42 according to the second structural example is shown in FIG. 29.

In the static field adjustment apparatus 42 according to the second structural example, the sizes and the shapes of the magnetic members 71 are different. In the example in FIG. 29, with reference to FIG. 25, a magnetic member 71 that extends over two areas in the horizontal direction, and a magnetic member 71 that extends over three or more areas in the vertical direction are disposed.

The arrangement of the first partition members 32 and 33 may be adjusted in accordance with the sizes and the shapes of the magnetic members 71. For example, to dispose a magnetic member 71 across two areas in the horizontal direction, one first partition member 33 in the vertical direction is removed.

The second layer 35 of the static field adjustment apparatus 42 according to the second structural example is shown in FIG. 30.

In the second layer 35, the arrangement of the second partition members 37 is adjusted in accordance with the sizes and the shapes of the magnetic members 71 disposed in the first layer 30.

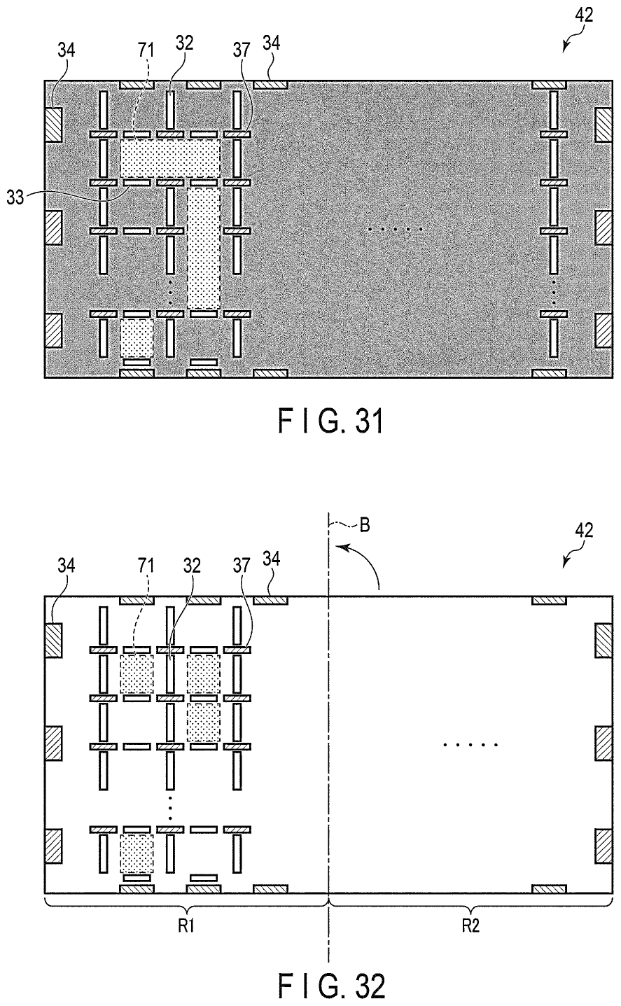

Next, the static field adjustment apparatus 42 in which the first layer 30 and the second layer 35 are stacked according to the second structural example is described with reference to FIG. 31.

FIG. 31 is a conceptual diagram showing a member layout between the layers in a case where the first layer 30 and the second layer 35 are stacked and fixed, as in FIG. 27. By removing, as appropriate, the first partition members 32 and 33 and the second partition members 37 in accordance with the sizes and shapes of the magnetic members 71, and adjusting the walls formed with the respective partition members, it is possible to place the magnetic members 71 having different sizes and shapes, regardless of the sizes and shapes of the magnetic members 71.

Note that, in the examples shown in FIGS. 25 to 31, it is assumed that the rectangular magnetic members 71 are used. However, any shape such as a square, a circle, a cylinder, a sphere, a polygon, a ring-like shape, or a tube-like shape may be used, as long as fine adjustment of the magnetic field is facilitated. In this case, the shapes of the first partition members 32 and 33 and the second partition members 37 are changed in accordance with the shapes of the magnetic members 71.

Although the examples in which the second partition members 37 are disposed on the second layer 35 have been described, the present embodiment is not limited to this, and the first partition members 32 and 33 and the second partition members 37 may be disposed on the first layer 30, the second layer 35 may have only the second sheet 36, and the second sheet 36 may fix the magnetic members 71 to the respective partition members. Further, the static field adjustment apparatus 42 does not necessarily have a two-layer structure, but may have a structure in which three or more layers are stacked. Alternatively, the static field adjustment apparatus 42 may have a two-layer structure in which one sheet is folded back.

Referring now to FIG. 32, a third structural example of the static field adjustment apparatus 42 is described.

The static field adjustment apparatus 42 according to the third structural example is formed with one sheet, and is divided into a first region R1 and a second region R2, with the reference line being a folding line B.

In the first region R1, the first partition members 32 and 33 and the second partition members 37 are formed, and the magnetic members 71 are disposed in the areas surrounded by the first partition members 32 and 33 and the second partition members 37. On the other hand, no partition members are formed in the second region R2.

By the folding line B, the second region R2 is folded back toward the first region R1 and is bonded thereto, so that the static field adjustment apparatus 42 having a two-layer structure can be formed. After the bonding, the sheet is fixed by the fixing portions 34, for example.

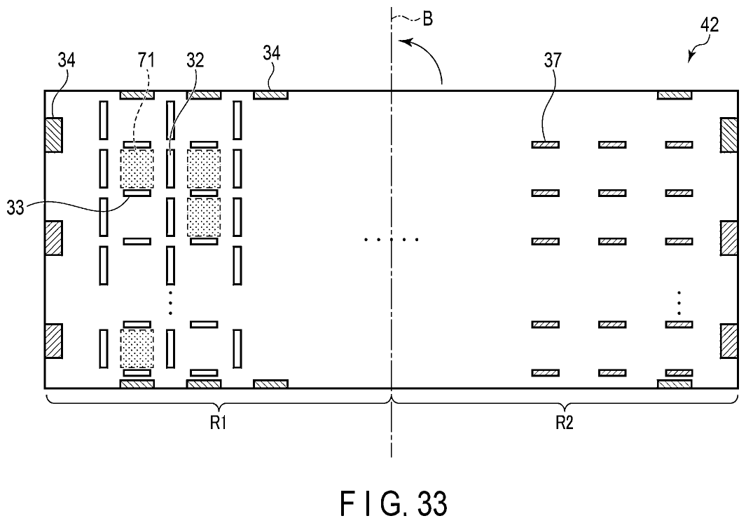

Next, a fourth structural example of the static field adjustment apparatus 42 is described with reference to FIG. 33.

In the static field adjustment apparatus 42 according to the fourth structural example, the first partition members 32 and 33 are formed in the first region R1, and the second partition members 37 are formed in the second region R2. As the second region R2 is folded back toward the first region R1 and is bonded thereto, the static field adjustment apparatus 42 having a two-layer structure can be formed, as in the case shown in FIG. 32. This structure is the same as that in a case where the first layer 30 shown in FIG. 25 and the second layer 35 shown in FIG. 26 are stacked.

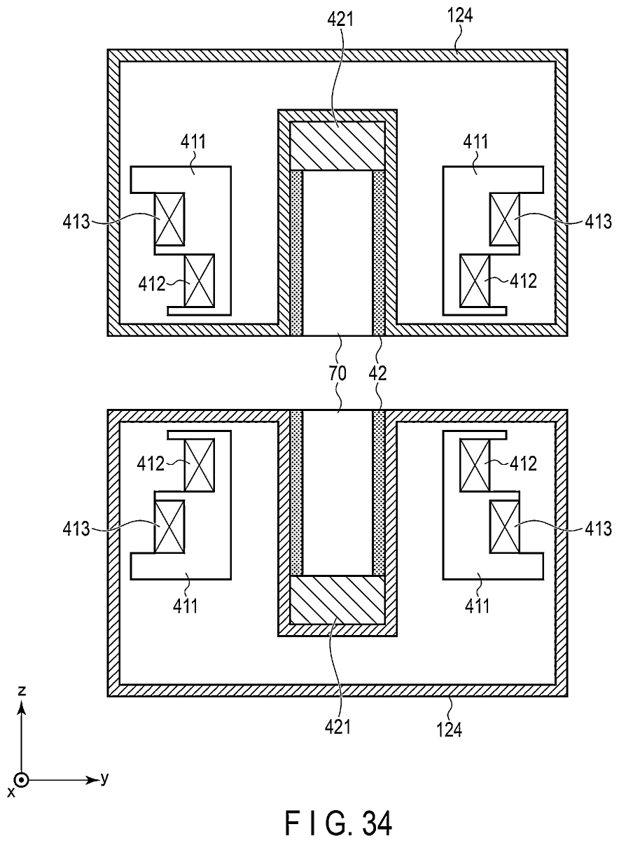

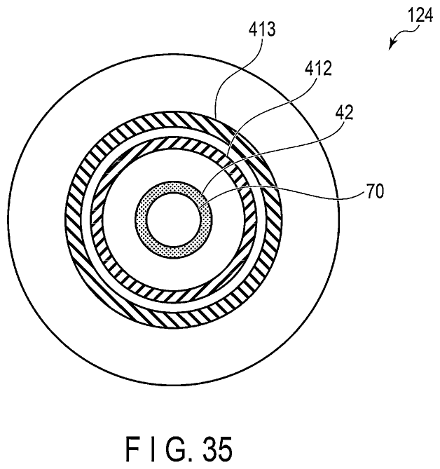

Next, the first structural example in a case where the static field adjustment apparatus 42 is inserted into the gantry 11 is described with reference to FIGS. 34 and 35.

FIG. 34 is a cross-sectional view taken along the center portion of the cylinder formed with the first container 124 of the upper housing 122 and the first container 124 of the lower housing 121.

Each first container 124 according to the third embodiment includes two superconducting coils (a first superconducting coil 412 and a second superconducting coil 413), a support base 411, a spacer 421, a static field adjustment apparatus 42, and a winding core 70.

The first container 124 has a cylindrical central portion formed in a recessed shape. Note that each first container 124 may be formed in a bore-like shape in which the cylindrical central portion is open. The first container 124 described below is not necessarily integrally molded, but may be formed with a plurality of members that are joined as appropriate.

A first superconducting coil 412 and a second superconducting coil 413 are disposed so that the openings of the loop face in the vertical direction (the z-axis direction in FIG. 34). The first superconducting coil 412 and the second superconducting coil 413 are designed so that currents in directions opposite to each other flow so as to reduce a leakage magnetic field. Although two superconducting coils are shown as an example herein, the present embodiment is not limited to this, and a static magnetic field may be formed by three or more superconducting coils. Hereinafter, the first superconducting coil 412 and the second superconducting coil 413 will also be collectively referred to as the “superconducting coils” as necessary.

The support base 411 is stored in the first container 124, and supports the superconducting coils.

The static field adjustment apparatus 42 wound around the winding core 70 is inserted into the recessed portion of the cylindrical central portion of the first container 124. The winding core 70 and the static field adjustment apparatus 42 may have a fixing mechanism, such as a key groove, with which the winding core 70 is fixed to the static field adjustment apparatus 42 without rotating, for example.

Note that, in the above example, a case where the static field adjustment apparatus 42 has a two-layer structure has been described as an example, but the static field adjustment apparatus 42 may be formed with one sheet. For example, the first partition members 32 and 33 and the second partition members 37 are formed on the first sheet 31, and the magnetic members 71 are fixed to predetermined areas with an adhesive. As the surface to which the magnetic members 71 are fixed is wound around the winding core 70, the magnetic members 71 can be fixed by the winding core 70 in addition to an adhesive.

The spacer 421 is provided to raise the winding core 70 and the static field adjustment apparatus 42. Note that, in a case where the first container 124 does not need the spacer 421, such as a case where the depth of the concave shape of the first container 124 is small, the spacer 421 may not be provided.

FIG. 35 is a drawing showing the positional relationship between the superconducting coils and the static field adjustment apparatus 42 in a case where the side of the gantry 11 is viewed from the imaging space 210. As shown in FIG. 35, the superconducting coils are arranged in a loop-like shape so that the opening faces in the z-axis direction. The static field adjustment apparatus 42 wound around the winding core 70 is disposed on the inner peripheral side of a superconducting coil (in this case, the inner peripheral side of the first superconducting coil 412).

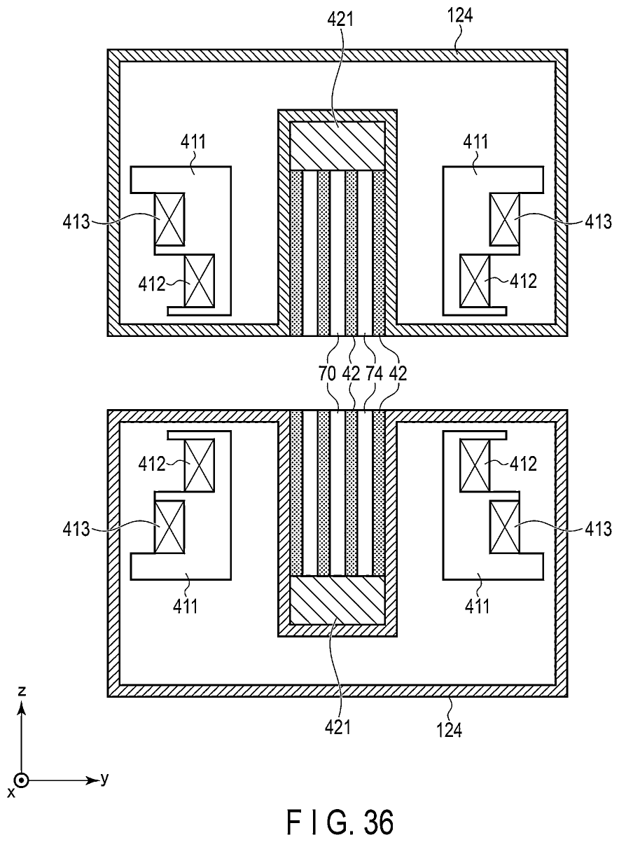

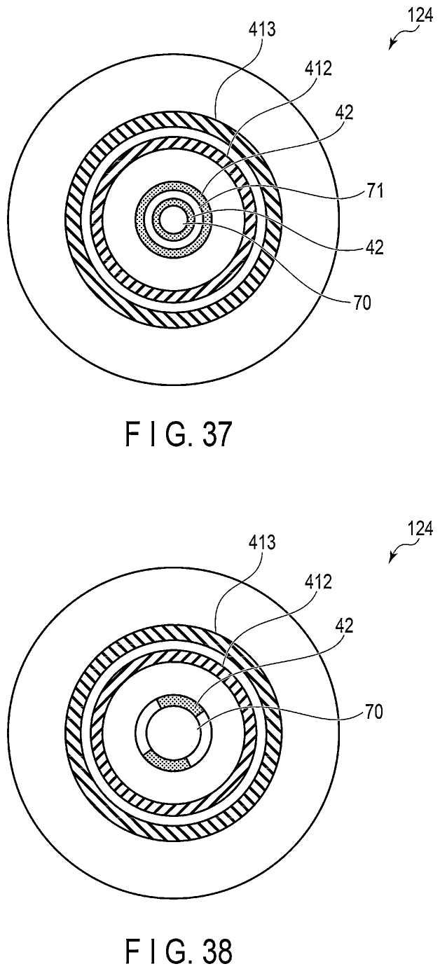

Next, the second structural example in a case where the static field adjustment apparatus 42 is inserted into the gantry 11 is described with reference to FIGS. 36 and 37.

FIG. 36 is a cross-sectional view taken along the central portion of the cylinder of the first containers 124 in the second structural example in a case where the static field adjustment apparatus 42 is inserted into the gantry 11. FIG. 37 is a drawing showing the positional relationship between the superconducting coils and the static field adjustment apparatus 42 in the second structural example in a case where the static field adjustment apparatus 42 is inserted into the gantry 11.

In the second structural example, a plurality of static field adjustment apparatuses 42 is inserted into the gantry 11. Here, a first static field adjustment apparatus 42 is wound around the winding core 70, and a spacer 74 is wound around the first static field adjustment apparatus 42. A second static field adjustment apparatus 42 is wound around the spacer 74. The spacer 74 may be formed with the same material as the winding core 70, or may be formed with a different material. As the spacer 74 is inserted, the space between the first static field adjustment apparatus 42 and the second static field adjustment apparatus 42 can be adjusted.

In this manner, the plurality of static field adjustment apparatuses 42 may be arranged as a plurality of layers. Note that the structure between the respective static field adjustment apparatuses 42 is a fixed structure in which the static field adjustment apparatuses 42 are not moved by the spacer 74. Further, the plurality of static field adjustment apparatuses 42 is not necessarily provided in the form of layers, but one static field adjustment apparatus 42 may be provided and be spirally wound together with the spacer 74.

Next, the positional relationship between the superconducting coils and the static field adjustment apparatuses 42 in the third structural example in a case where the static field adjustment apparatus 42 is inserted into the gantry 11 is shown in FIG. 38.

As shown in FIG. 38, a plurality of static field adjustment apparatuses 42 may be partially inserted in a circumferential direction. That is, the static field adjustment apparatuses 42 are not wound in a cylindrical shape, but may be formed in a columnar shape having a curvature in the circumferential direction of the superconducting coils. In other words, the static field adjustment apparatuses 42 may be formed in a semi-cylindrical shape, and be inserted on the inner peripheral side of the superconducting coils.

As shown in FIGS. 36 to 38, a plurality of static field adjustment apparatuses 42 is used, and some of the static field adjustment apparatuses 42 are moved in and out while a static magnetic field is generated, for example. Thus, fine adjustment of the static magnetic field can be performed without magnetization and demagnetization.

According to the third embodiment described above, a static field adjustment apparatus having partition members that holds a plurality of magnetic members on or in a flexible sheet is generated. Also, with a two-layer structure, a static field adjustment apparatus that includes the first partition members and the second partition members is formed. The first partition members are formed on the surface of the first layer on which the magnetic members are disposed, and partition the areas in which the magnetic members are disposed. The second partition members are formed on the second layer so as to surround the areas in which the magnetic members are disposed, being placed in the gaps in the first partition members, in a case where the first layer and the second layer are stacked. The first partition members and the second partition members are formed at positions and with sizes that do not interfere with each other in a case where the static field adjustment apparatus is rolled into a cylindrical shape.

Accordingly, compared with conventional shim trays, the static field adjustment apparatus can adjust a magnetic field as in handling a plurality of shim trays. Thus, the number of processing steps can be advantageously reduced. Further, a shimming device that has a high degree of freedom and is capable of appropriately adjusting a magnetic field can also be provided in a facing-type magnetic resonance imaging apparatus not including a large space for arrangement, compared with a conventional cylindrical magnetic resonance imaging apparatus including a large space for arranging shim trays.

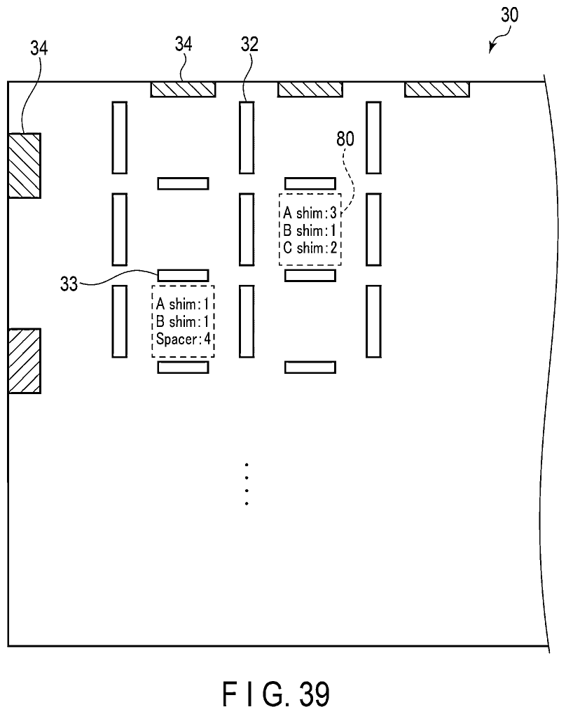

Referring now to FIG. 39, a method for aiding arrangement of the magnetic members 71 in the static field adjustment apparatus 42 according to the third embodiment is described.

FIG. 39 shows an example in which guide information 80 is displayed on the sheet (the first layer 30, for example) on which the magnetic members 71 are disposed. Specifically, in the areas that are partitioned by the respective partition members and should have the magnetic members 71 to be disposed therein, at least one piece of information, such as the type, the number, and the shape of the magnetic members 71, the number of the spacers 72 to be disposed in place of the magnetic members 71, whether or not the partition members surrounding the areas are to be removed, or the partition members to be removed in a case where the partition members are to be removed, is displayed as the guide information 80 on the sheet. The type of the magnetic members 71 indicates a difference in the type or the thickness of the magnetic members, for example. Note that information regarding a difference in shape may also be handled as the type of the magnetic members 71.

In the example in FIG. 39, “A shim: 3, B shim: 1, C shim: 2” and “A shim: 1, B shim: 1, spacer: 4” are displayed in the areas in which the magnetic members 71 are to be disposed. With this display, it is possible to grasp the type and the number of the magnetic members 71 to be disposed, the presence or absence of spacers, and the like.

Note that the guide information 80 may be determined by general magnetic field adjustment software, for example. Specifically, the guide information 80 may be determined by magnetic field adjustment software, taking into consideration at least one piece of information about the static magnetic field inside and outside the imaging space 210, the electromagnetic force and the magnetic susceptibility of the superconducting coils and the magnetic members, the gradient field, the magnetic field distribution by the RF coil, the pulse sequence to be used, and the information about the image reconstruction technique.

Also, the guide information 80 may be printed directly on the sheet, or may be displayed on the sheet by an optical projection means such as projection mapping, for example. In a case where the guide information 80 is projected by the optical projection means, the guide information may be projected on the surface on which the magnetic members 71 are disposed, may be projected from the back surface of the surface on which the magnetic members 71 are disposed, or may be projected from both surfaces. Alternatively, if the sheet is translucent, and the table on which the sheet is placed is a display, the guide information 80 may be displayed on the display, and the operator may check the guide information 80 while seeing through the sheet.

According to the embodiment described above, the guide information is printed directly on a sheet, or the guide information is displayed on a sheet by an optical projection means, in the areas in which the magnetic members are to be disposed. As a result, the operator can easily grasp the positions, the type, the number, and the shape of the magnetic members to be disposed, the necessity of removal of each partition member, and the like, without an increase in the number of processing steps. Thus, it is possible to provide a shimming device that is capable of appropriate magnetic field adjustment and has a high degree of freedom.

Note that, in the present embodiment, an open-type magnetic resonance imaging system is assumed. However, the static field adjustment apparatus according to the above-described embodiment can also be adopted in a general cylindrical magnetic resonance imaging apparatus. For example, instead of a plurality of shim trays, the static field adjustment apparatus according to the above-described embodiment can be inserted.

Alternatively, the static field adjustment apparatus 42 may be adopted in a magnetic resonance imaging system using a superconducting magnet on only one side, in which the gradient field coil 43 and the transmitter coil 45 are stacked in the upper housing 122 or the lower housing 121 described in the present embodiment. If an imaging space can be formed in a lower space in the upper housing 122 or in an upper space in the lower housing 121, imaging can be performed in the same manner as in an open-type magnetic resonance imaging system.

### Fourth Embodiment

In a fourth embodiment, it is assumed that the structures of the static field adjustment apparatuses 42 according to the first to third embodiments described above are combined as appropriate.

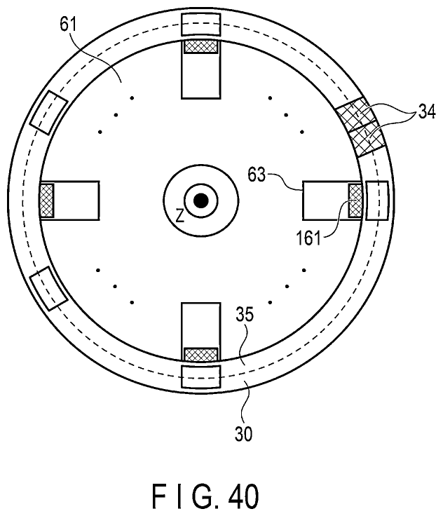

FIG. 40 shows a conceptual diagram of a static field adjustment apparatus 42 according to the fourth embodiment.

FIG. 40 is a plan view of a static field adjustment apparatus including the same lidded holding member as that shown in FIG. 18, and shows an example in which the lid portion 171 according to the second embodiment is formed by the sheet-like static field adjustment apparatus according to the third embodiment. Specifically, not only can magnetic members 71 and spacers 72 be stored in accommodating portions 63 of holding members 61, but the magnetic members 71 and the spacers 72 can also be stored between a first layer 30 and a second layer 35 that act as lids surrounding the outer periphery of the holding members 61. The storage positions (rectangular areas in the first layer 30 and the second layer 35 in FIG. 40) of the magnetic members 71 and the spacers 72 surrounded by first partition members and second partition members between the first layer 30 and the second layer 35 may be positions facing the accommodating portions 63 or positions deviating from the accommodating portions 63.

According to the fourth embodiment described above, the structure of the lid portion according to the second embodiment is formed with the first layer and the second layer according to the third embodiment. Thus, the installation positions of the magnetic members can be more flexibly designed.

According to at least one of the embodiments described above, the spatial uniformity of a static magnetic field distribution can be enhanced.

The term “processor” used in the above description means a CPU, a GPU, or a circuit such as an application specific integrated circuit (ASIC), a programmable logic device (a simple programmable logic device (SPLD), for example), a complex programmable logic device (CPLD), or a field programmable gate array (FPGA). The processor achieves a function by reading and executing a program stored in a storage circuit. Note that, instead of storing a program in a storage circuit, it is possible to incorporate the program directly into a circuit in the processor. In this case, the processor achieves a function by reading and executing the program incorporated into the circuit. On the other hand, in a case where the processor is an ASIC, for example, the function is incorporated as a logic circuit into the circuit in the processor, instead of the program being stored into a storage circuit. Note that each processor of the present embodiment is not necessarily formed as a single circuit, but a plurality of independent circuits may be combined to form one processor, and the functions thereof may be achieved. Further, a plurality of constituent elements in FIG. 1 may be integrated into one processor to achieve the functions thereof.

The following are supplementary notes.

### 1-1

A static field adjustment apparatus including
a plurality of holding members that hold a magnetic member for adjusting a distribution of a static magnetic field to be used in magnetic resonance imaging, in which
all or some of the holding members are stacked in an axial direction of an annular magnet that generates the static magnetic field, in a first space on an internal diameter side of the magnet.

### 2-1

The static field adjustment apparatus according to (1-1), further including a support member that supports the holding members in a stackable manner in the axial direction.

### 3-1

The static field adjustment apparatus according to (2-1), in which
each of the holding members has an annular shape in which a hollow portion is formed, and
the support member includes a fixing rod inserted into the hollow portion of each of the holding members.

### 4-1

The static field adjustment apparatus according to (3-1), in which the support member includes a pair of fastening tools that fix, to the fixing rod, holding members at both ends of a plurality of holding members through which the fixing rod is inserted.

### 5-1

The static field adjustment apparatus according to (3-1), in which the holding members and the fixing rod each include a protrusion and a groove that are fittable to each other.

### 6-1

The static field adjustment apparatus according to (3-1), in which the fixing rod includes a first accommodating portion into which a magnetic sensor for detecting a distribution of a magnetic field in the axial direction is insertable.

### 7-1

The static field adjustment apparatus according to (2-1), in which
each of the holding members includes, as the support member:
a protrusion on a first surface orthogonal to the axial direction, and
a recess on a second surface on a side opposite to the first surface, the recess being fittable to the protrusion provided on the first surface of another holding member.

### 8-1

The static field adjustment apparatus according to (2-1), in which the support member supports a spacer for adjusting a distance between the holding members in a stackable manner.

### 9-1

The static field adjustment apparatus according to (1-1), in which each of the holding members includes a plurality of second accommodating portions that communicate with an opening formed in a surface of the holding member and is capable of accommodating the magnetic member.

### 10-1

The static field adjustment apparatus according to (9-1), in which a lid for closing an opening of each of the second accommodating portions is attached to each of the holding members.

### 11-1

The static field adjustment apparatus according to (9-1), in which each of the second accommodating portions is formed on an outer peripheral surface, an inner peripheral surface, a top surface, and/or a bottom surface of the holding member.

### 12-1

The static field adjustment apparatus according to (9-1), in which each of the second accommodating portions is capable of accommodating, in addition to the magnetic member, a spacer for adjusting and/or fixing a position of the magnetic member.

### 13-1

The static field adjustment apparatus according to (1-1), in which a
ll or some of the holding members include a plurality of holder layers that are arranged in a radial direction orthogonal to the axial direction, and
each of the holder layers is capable of holding the magnetic member.

### 14-1

The static field adjustment apparatus according to (13-1), in which the holder layers other than the holder layer on the innermost periphery among the holder layers each include a first accommodating portion having an opening in an outer peripheral surface, a second accommodating portion having an opening in an inner peripheral surface, a third accommodating portion having an opening in a top surface, and/or a fourth accommodating portion having an opening in a bottom surface, to hold the magnetic member.

### 15-1

The static field adjustment apparatus according to (1-1), in which all or some of the holding members are arranged in a hollow portion formed by a housing that accommodates the magnet, in the first space.

### 16-1

The static field adjustment apparatus according to (15-1), in which all or some of the holding members are disposed, with a spacer being interposed between a bottom surface and/or an inner wall surface in contact with the hollow portion in the housing, the spacer being for adjusting positions of all or some of the holding members.

### 17-1

The static field adjustment apparatus according to (1-1), in which
some of the holding members are disposed in the internal diameter space, and
the remaining ones of the holding members are stacked in the axial direction of the magnet in a second space other than the first space in a radial direction of the magnet.

### 18-1

The static field adjustment apparatus according to (17-1), in which the second space is a space outside a housing that accommodates the magnet, in a space on an outer side of the first space in the radial direction of the magnet.

### 19-1

The static field adjustment apparatus according to (18-1), in which the remaining ones of the holding members are disposed in a non-penetrating hollow portion or a penetrating hollow portion in the axial direction of the magnet, the non-penetrating hollow portion or the penetrating hollow portion being the second space, inside or outside another housing located on an outer side of the housing that accommodates the magnet.

### 20-1

A magnetic resonance imaging system including:
a magnet that has an annular shape and generates a static magnetic field; and
a plurality of holding members that are capable of holding a magnetic member for adjusting a distribution of the static magnetic field, in which
the respective holding members are stacked in an axial direction of the annular magnet that generates the static magnetic field, at least on an internal diameter side of the magnet.

### 1-2

A static field adjustment apparatus including:
a holding member including a plurality of accommodating portions into and from which a magnetic member for correcting a distribution of a static magnetic field to be used in magnetic resonance imaging is inserted and removed; and
a lid portion that is attached to the holding member so as to cover two or more accommodating portions among the accommodating portions.

### 2-2

The static field adjustment apparatus according to (1-2), in which
the lid portion includes a film member that is in the form of a film and has flexibility, and
two or more fixing tools for fixing the magnetic member accommodated in the two or more accommodating portions are provided on one surface of the film member at two or more positions corresponding to the two or more accommodating portions, respectively.

### 3-2

The static field adjustment apparatus according to (2-2), in which each of the two or more fixing tools is a spacer that is inserted into the accommodating portion.

### 4-2

The static field adjustment apparatus according to (3-2), in which
each of the two or more fixing tools includes a plurality of frame members that are arranged so as to be insertable into the accommodating portions, and
the frame members are arranged, with a space being left in between.

### 5-2

The static field adjustment apparatus according to (4-2), in which the frame members have a predetermined thickness in a depth direction of the housing portions, and are stacked in the depth direction, depending on a total thickness of the magnetic members accommodated in the accommodating portions.

### 6-2

The static field adjustment apparatus according to (1-2), in which the holding member and the lid portion each include a pair of fastening tools to be detachably joined to each other.

### 7-2

The static field adjustment apparatus according to (1-2), in which
the holding member has an annular shape, and
the accommodating portions are formed on an inner peripheral surface or an outer peripheral surface of the holding member.

### 8-2

The static field adjustment apparatus according to (7-2), in which the lid portion includes a film member that is in the form of a film and has flexibility, and covers the two or more accommodating portions provided on the inner peripheral surface or the outer peripheral surface of the holding member with one sheet.

### 9-2

The static field adjustment apparatus according to (8-2), in which
a long axis direction of the film member has a length sufficient to be wound around the inner peripheral surface or the outer peripheral surface of the holding member, and
a pair of fastening tools to be detachably joined to each other are provided at both ends of the film member in the long axis direction.

### 10-2

The static field adjustment apparatus according to (1-2), in which
a plurality of the holding members are provided, and
the holding members are stacked in an axial direction of an annular superconducting coil that generates the static magnetic field.

### 11-2

A magnetic resonance imaging system including:
a cylindrical superconducting coil that generates a static magnetic field;
a holding member including a plurality of accommodating portions into and from which a magnetic member for correcting a distribution of the static magnetic field is inserted and removed; and
a lid portion that is attached to the holding member so as to cover two or more accommodating portions among the accommodating portions.

### 1-3

A static field adjustment apparatus including:
a sheet having flexibility; and
a partition member for holding a plurality of magnetic members for adjusting a magnetic field on or in the sheet.

### 2-3

The static field adjustment apparatus according to (1-3), in which the sheet includes:
a first layer on which the partition member is formed; and
a second layer that is stacked on a surface of the first layer on which the magnetic members are disposed, and fixes the magnetic members.

### 3-3

The static field adjustment apparatus according to (2-3), in which the partition member includes a first partition member and a second partition member,
the first partition member is formed on the surface of the first layer on which the magnetic members are disposed, and partitions areas in which the magnetic members are disposed, and
the second partition member is formed on a surface of the second layer facing the first layer so as to surround the areas in which the magnetic members are dispose, being placed in gaps in the first partition member when the first layer and the second layer are stacked.

### 4-3

The static field adjustment apparatus according to (3-3), in which the sheet has flexibility, and
the static field adjustment device further includes a fixing portion that winds and fixes the sheet.

### 5-3

The static field adjustment apparatus according to (4-3), in which the first partition member and the second partition member are formed in such a shape and a layout that adjacent members do not interfere with each other when winding is performed in a state where the first layer and the second layer are stacked.

### 6-3

The static field adjustment apparatus according to (3-3), in which, when the second layer is stacked on the first layer, the areas in which the magnetic members are fixed are formed in a grid-like form by the first partition member and the second partition member.

### 7-3

The static field adjustment apparatus according to (3-3), in which the first partition member and the second partition member include a groove or a recess for fixing the magnetic member.

### 8-3

The static field adjustment apparatus according to (1-3), in which the sheet is divided into a first region and a second region,
in the first region, a first partition member that partitions the areas in which the magnetic members are disposed into rectangles is formed, and,
a second partition member that is disposed in a gap in the first partition member when the second region is folded back toward the first region and is stacked on the first region is formed.

### 9-3

The static field adjustment apparatus according to (1-3), in which the surface on which the magnetic members are disposed is wound around a winding core member, to fix the magnetic members.

### 10-3

A superconducting magnet including:
a loop-like superconducting coil that forms a static magnetic field;
a cryostat that is a housing for storing the superconducting coil, and in which a space on an inner peripheral side of the loop of the superconducting coil has a recess-like shape or an opening; and
the static field adjustment apparatus according to (1-3) that is inserted into the recess-like space of the cryostat in a state of being wound around a winding core member.

### 11-3

An arrangement aid method for aiding arrangement of magnetic members in a static field adjustment apparatus that includes a sheet having flexibility, and a partition member for holding a plurality of magnetic members for adjusting a magnetic field on or in the sheet,
the arrangement aid method including displaying at least one piece of guide information about positions at which the magnetic members are disposed, the number, and the type, by printing on the sheet or a means of optical projection onto the sheet.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A static field adjustment apparatus comprising
a plurality of holding members that hold a magnetic member for adjusting a distribution of a static magnetic field to be used in magnetic resonance imaging, wherein
all or some of the holding members are stacked in an axial direction and/or a radial direction of a magnet that has an annular shape and generates the static magnetic field, in a first space on an internal diameter side of the magnet.

2. The static field adjustment apparatus according to claim 1, further comprising a first accommodating portion into which a magnetic sensor for detecting a distribution of a magnetic field in the axial direction and/or the radial direction is insertable.

3. The static field adjustment apparatus according to claim 2, wherein if the holding members are stacked in the axial direction,
each of the holding members includes:
a protrusion on a first surface orthogonal to the axial direction, and
a recess on a second surface on a side opposite to the first surface, the recess being fittable to the protrusion provided on the first surface of another holding member.

4. The static field adjustment apparatus according to claim 1, wherein if the holding members are stacked in the radial direction,
each of the holding members includes:
a protrusion on a first surface orthogonal to the radial direction, and
a recess on a second surface on a side opposite to the first surface, the recess being fittable to the protrusion provided on the first surface of another holding member.

5. The static field adjustment apparatus according to claim 1, wherein if the holding members are stacked in the radial direction,
the holding members are supported by a support member that penetrates in the radial direction.

6. The static field adjustment apparatus according to claim 1, further comprising a support member that supports a spacer for adjusting a space between the holding members in a stackable manner.

7. The static field adjustment apparatus according to claim 1, wherein each of the holding members includes a plurality of second accommodating portions that communicate with an opening formed in a surface of the holding member and is capable of accommodating the magnetic member.

8. The static field adjustment apparatus according to claim 7, wherein each of the holding members has a lid for closing an opening of each of the second accommodating portions.

9. The static field adjustment apparatus according to claim 7, wherein each of the second accommodating portions is formed on an outer peripheral surface, an inner peripheral surface, a top surface, and/or a bottom surface of the holding member.

10. The static field adjustment apparatus according to claim 7, wherein each of the second accommodating portions is capable of accommodating, in addition to the magnetic member, a spacer for adjusting and/or fixing a position of the magnetic member.

11. The static field adjustment apparatus according to claim 1, wherein if the holding members are stacked in the radial direction, a holding member other than a holding member on an innermost periphery among the holding members includes a first accommodating portion having an opening in an outer peripheral surface, a second accommodating portion having an opening in an inner peripheral surface, a third accommodating portion having an opening in a top surface, and/or a fourth accommodating portion having an opening in a bottom surface, to hold the magnetic member.

12. The static field adjustment apparatus according to claim 1, wherein the all or some of the holding members are arranged in a hollow portion formed by a housing that accommodates the magnet, in the first space.

13. The static field adjustment apparatus according to claim 12, wherein the all or some of the holding members are disposed, with a spacer being interposed between a bottom surface and/or an inner wall surface in contact with the hollow portion in the housing, the spacer being for adjusting positions of the all or some of the holding members.

14. The static field adjustment apparatus according to claim 1, wherein some of the holding members are disposed in the first space, and a remaining holding member of the holding members is stacked in the axial direction of the magnet in a second space other than the first space in the radial direction of the magnet.

15. The static field adjustment apparatus according to claim 14, wherein the second space is a space outside a housing that accommodates the magnet, in a space on an outer side of the first space in the radial direction of the magnet.

16. The static field adjustment apparatus according to claim 15, wherein the remaining holding member is disposed in a non-penetrating hollow portion or a penetrating hollow portion in the axial direction of the magnet, the non-penetrating hollow portion or the penetrating hollow portion being the second space, inside or outside another housing located on an outer side of the housing that accommodates the magnet.

17. The static field adjustment apparatus according to claim 1, wherein each of the holding members forms of (a) a sheet having flexibility and (b) a partition member for holding a plurality of magnetic members for adjusting a magnetic field on or in the sheet.

18. A magnetic resonance imaging system comprising:
a magnet that has an annular shape and generates a static magnetic field; and
a plurality of holding members that are capable of holding a magnetic member for adjusting a distribution of the static magnetic field, wherein
all or some of the holding members are stacked in an axial direction and/or a radial direction of the magnet, at least in a first space on an internal diameter side of the magnet.
